(19) United States
(12) Patent Application Publication
(10) Pub. No.: US 2025/0126771 A1
(43) Pub. Date: Apr. 17, 2025

(54) METHOD OF MANUFACTURING SEMICONDUCTOR MEMORY DEVICE

(71) Applicant: Samsung Electronics Co., Ltd., Suwon-si (KR)

(72) Inventor: Jinbum Kim, Suwon-si (KR)

(21) Appl. No.: 18/747,624

(22) Filed: Jun. 19, 2024

(30) Foreign Application Priority Data
Oct. 12, 2023 (KR) 10-2023-0136223

(51) Int. Cl. H10B 12/00

(52) U.S. Cl. CPC H10B 12/05

(57) ABSTRACT

A method of manufacturing a semiconductor memory device includes forming a metal seed pattern having a plurality of openings on a substrate, forming a metal silicide pattern from the substrate and the metal seed pattern, growing a single crystal semiconductor pattern in a vertical direction at an interface between the substrate and the metal silicide pattern where the vertical direction is perpendicular to the substrate, and growing a sacrificial semiconductor pattern in the vertical direction at an interface between the metal silicide pattern and the single crystal semiconductor pattern.

### CROSS-REFERENCE TO RELATED APPLICATION

This application is based on and claims priority under 35 U.S.C. § 119 to Korean Patent Application No. 10-2023-0136223, filed on Oct. 12, 2023, in the Korean Intellectual Property Office, the disclosure of which is incorporated by reference herein in its entirety.

### BACKGROUND

The inventive concept relates to a method of manufacturing a semiconductor memory device, and more particularly, to a method of manufacturing a three-dimensional semiconductor memory device.

The need for electronic products to be miniaturized, multifunctional, and high-performance requires high-capacity semiconductor memory devices. Since the degree of integration of conventional two-dimensional semiconductor memory devices is mainly determined by a decrease in an area occupied by unit memory cells, improving the degree of integration of two-dimensional semiconductor memory devices is limited by the physical limitations of an ultra-high integrated semiconductor manufacturing process. Accordingly, as a solution to improve the degree of integration, a three-dimensional semiconductor memory device with a plurality of memory cells stacked in a vertical direction is attracting attention.

### SUMMARY

The inventive concept provides a method of manufacturing a semiconductor memory device with improved reliability and integration.

According to some embodiments of the inventive concept, there is provided a method of manufacturing a semiconductor memory device. The method of manufacturing the semiconductor memory device includes forming a metal seed pattern having a plurality of openings on a substrate, forming a metal silicide pattern from the substrate and the metal seed pattern, growing a single crystal semiconductor pattern in a vertical direction at an interface between the substrate and the metal silicide pattern where the vertical direction is perpendicular to the substrate, and growing a sacrificial semiconductor pattern in the vertical direction at an interface between the metal silicide pattern and the single crystal semiconductor pattern.

According to some embodiments of the inventive concept, there is provided a method of manufacturing a semiconductor memory device. The method of manufacturing the semiconductor memory device includes forming a metal seed pattern on a substrate, forming a metal silicide pattern from the substrate and the metal seed pattern, forming a eutectic layer of a metal-semiconductor material by heating the metal silicide pattern, and forming a patterned mold stack having a plurality of vertical holes exposing the substrate by alternately growing respective ones of a plurality of single crystal semiconductor patterns and respective ones of a plurality of sacrificial semiconductor patterns from a bottom surface of the eutectic layer one by one.

According to some embodiments of the inventive concept, there is provided a method of manufacturing a semiconductor memory device. The method of manufacturing the semiconductor memory device includes forming a metal seed pattern having a plurality of openings on a substrate, forming a metal silicide pattern from the substrate and the metal seed pattern, forming a eutectic layer of a metal-semiconductor material by heating the metal silicide pattern, forming a patterned mold stack having a plurality of vertical holes by alternately growing respective ones of a plurality of single crystal semiconductor patterns and respective ones of a plurality of sacrificial semiconductor patterns from a bottom surface of the eutectic layer, at least partially filling the plurality of vertical holes with a sacrificial insulating layer, forming a plurality of recesses that extend into the patterned mold stack and the sacrificial insulating layer in a vertical direction by anisotropically etching the patterned mold stack and the sacrificial insulating layer, and forming a buried insulating structure at least partially filling the plurality of recesses. The plurality of vertical holes have a constant horizontal width regardless of distance from the substrate, and the plurality of recesses have a tapered shape in which a width becomes narrower towards a top surface of the substrate.

### BRIEF DESCRIPTION OF THE DRAWINGS

Embodiments of the inventive concept will be more clearly understood from the following detailed description taken in conjunction with the accompanying drawings in which:

FIG. 1 is an equivalent circuit diagram illustrating a cell array of a semiconductor memory device according to some embodiments;

FIG. 2A is a plan view for explaining a semiconductor memory device according to some embodiments;

FIG. 2B is a cross-sectional view of a semiconductor memory device taken along a line X1-X1′ of FIG. 2A;

FIG. 2C is an enlarged view of an area “EX1” of FIG. 2B;

FIG. 2D is a cross-sectional view of a semiconductor memory device taken along a line X2-X2′ of FIG. 2A;

FIG. 3 is a flowchart illustrating a method of manufacturing a semiconductor memory device according to some embodiments;

FIGS. 4A, 9A, 10A, and 14A are plan views for describing a method of manufacturing a semiconductor memory device according some embodiments; FIGS. 4B, 5 to 8, 9B, 10B, 11 to 13, 14B, and 15 to 19 are cross-sectional views for describing a method of manufacturing a semiconductor memory device according to some embodiments; and

FIGS. 20A and 20B are cross-sectional views illustrating a method of manufacturing a semiconductor memory device according to some embodiments.

### DETAILED DESCRIPTION

Hereinafter, embodiments of the technical idea of the inventive concept will be described in detail with reference to the accompanying drawings. The same reference numerals are used for the same components in the drawings, and redundant descriptions thereof are omitted.

In the present specification, a vertical direction may be defined as a Z direction, and horizontal directions may be defined as directions each perpendicular to the Z direction. The first horizontal direction and the second horizontal direction may be defined as directions crossing each other. The first horizontal direction may be referred to as an X direction, and the second horizontal direction may be referred to as a Y direction. The vertical level may refer to a height level according to the vertical direction (Z direction). The horizontal width of a component may refer to the length of the component in the horizontal direction, and the vertical length of the component may refer to the length of the component in the vertical direction (Z direction).

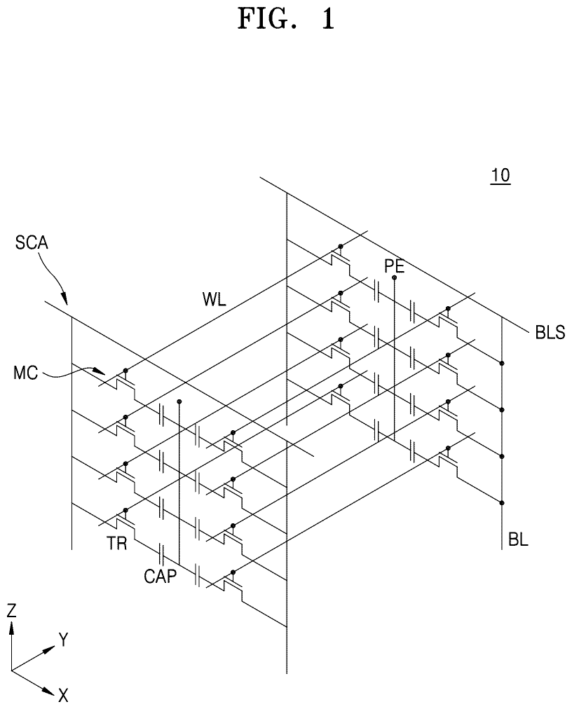

FIG. 1 is a circuit diagram illustrating a semiconductor memory device 10 according to some embodiments.

Referring to FIG. 1, the semiconductor memory device 10 may include a memory cell array SCA. The memory cell array SCA may include a plurality of bit lines BL, a plurality of word lines WL, and a plurality of memory cells MC.

According some embodiments, each of the plurality of memory cells MC may include a cell transistor TR and a cell capacitor CAP. The cell transistor TR and the cell capacitor CAP may be connected to each other. For example, any one of a source electrode and a drain electrode of the cell transistor TR may be connected to a lower electrode of the cell capacitor CAP.

According some embodiments, the plurality of memory cells MC may be repeatedly arranged in a first horizontal direction (X direction), a second horizontal direction (Y direction), and a vertical direction (Z direction). Each of the plurality of word lines WL may extend along the second horizontal direction (Y direction) and may be connected to the memory cells MC arranged in the second horizontal direction (Y direction). Each of the plurality of bit lines BL may extend along the vertical direction (Z direction), and may be connected to the memory cells MC arranged in the vertical direction (Z direction). Each of a plurality of bit line straps BLS may extend along the first horizontal direction (X direction), and may be connected to bit lines BL arranged in the first horizontal direction (X direction).

At least some of the plurality of memory cells MC may share an upper electrode PE of the capacitor CAP. For example, among the plurality of memory cells MC, a first memory cell pair arranged at the same vertical level and connected to different bit lines BL may share one upper electrode PE. According some embodiments, the upper electrode PE may extend along the vertical direction (Z direction) and may be connected to the plurality of memory cell pairs arranged in the vertical direction (Z direction).

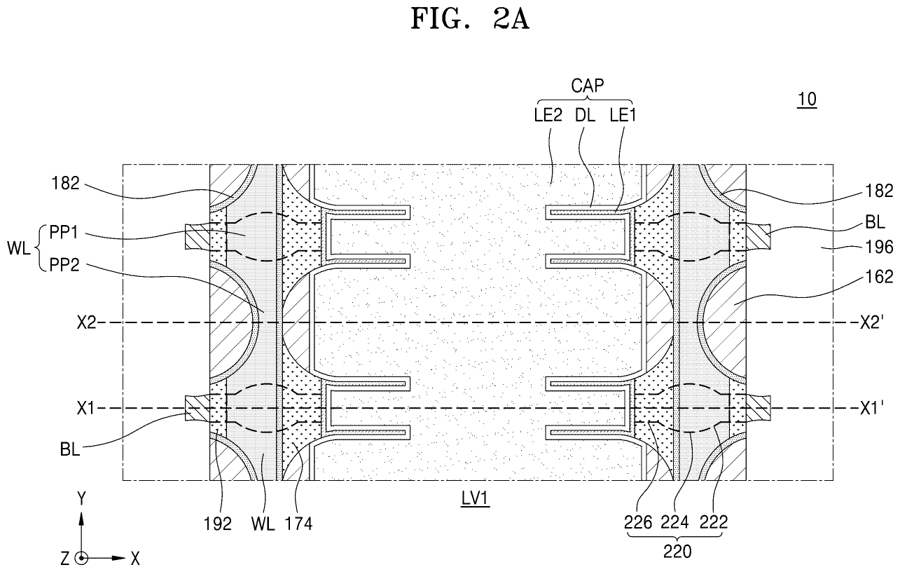

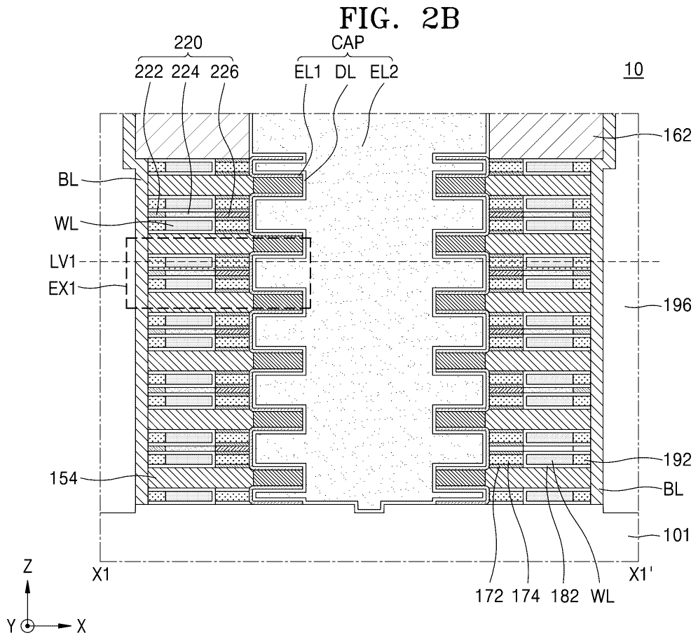

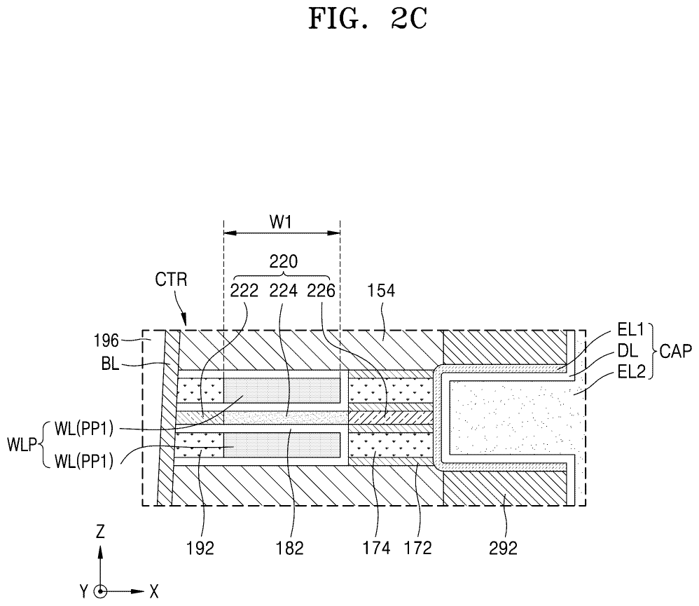

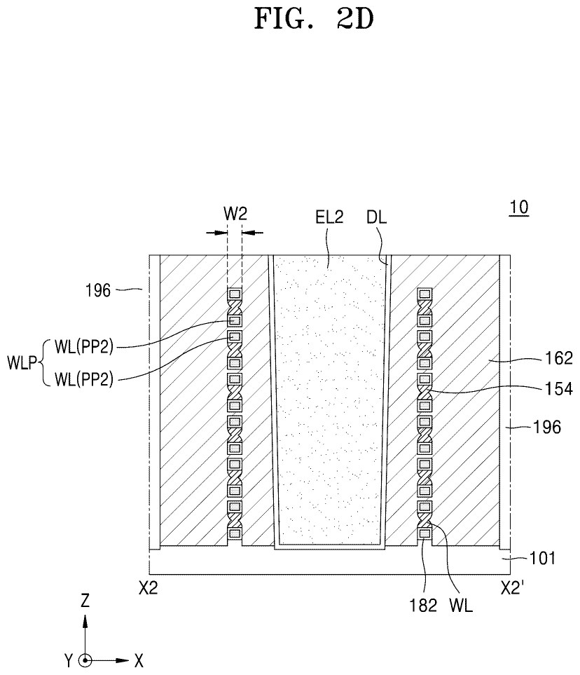

FIG. 2A is a plan view for explaining the semiconductor memory device 10 according some embodiments. Specifically, FIG. 2A shows a plan view at a first vertical level LV1 shown in FIG. 2B. FIG. 2B is a cross-sectional view of the semiconductor memory device 10 taken along a line X1-X1′ of FIG. 2A. FIG. 2C is an enlarged view of an area “EX1” of FIG. 2B. FIG. 2D is a cross-sectional view of the semiconductor memory device 10 taken along a line X2-X2′ of FIG. 2A.

Referring to FIGS. 2A to 2D, the semiconductor memory device 10 may include a substrate 101 and a plurality of memory cells repeatedly arranged in the first horizontal direction (X direction), the second horizontal direction (Y direction), and the vertical direction (Z direction) on the substrate 101. The plurality of memory cells respectively corresponds to the plurality of memory cells MC illustrated in FIG. 1. According some embodiments, the semiconductor memory device 10 may include a plurality of cell transistors CTR and a plurality of cell capacitors CAP arranged on the substrate 101.

According some embodiments, the substrate 101 may include Si, Ge, or SiGe. In some embodiments, for example, the substrate 101 may include a silicon-on-insulator (SOI) substrate or a germanium-on-insulator (GeOI) substrate.

The substrate 101 may have a top surface extending in a first horizontal direction (X direction) and a second horizontal direction (Y direction). For example, the top surface of the substrate 101 may have a normal line in a vertical direction (Z direction).

The substrate 101 may include a cell array region and a contact region (not shown). FIG. 2A illustrates a partial region of the cell array region. A wiring structure (not shown) connected to a plurality of cell transistors CTR and a plurality of cell capacitors CAP may be arranged in the contact region (not shown), and end portions of a plurality of word lines WL may be arranged.

Although not shown, a peripheral circuit (not shown) and a wiring layer (not shown) connected to the peripheral circuit may be formed on the substrate 101. For example, the peripheral circuit may include a metal oxide semiconductor field effect transistor (MOSFET) that includes a sub word line driver, a sense amplifier, etc., but is not limited thereto. A lower insulating layer (not shown) arranged to cover or overlap the peripheral circuit and the wiring layer may be formed on the substrate 101. In some other embodiments, the peripheral circuit (not shown) and the wiring layer (not shown) may be arranged on the plurality of cell transistors CTR and the plurality of cell capacitors CAP.

According to some embodiments, the plurality of cell transistors CTR may include a plurality of transistor bodies 220, a plurality of word lines WL, a gate dielectric layer 182, and a plurality of bit lines BL. According to some embodiments, the plurality of cell capacitors CAP may include a first electrode EL1, a second electrode EL2, and a capacitor dielectric layer DL between the first electrode EL1 and the second electrode EL2. For example, the second electrode EL2 may correspond to the upper electrode PE illustrated in FIG. 1.

According to some embodiments, the plurality of transistor bodies 220 each may have a bar shape extending in the first horizontal direction (X direction), and may be repeatedly arranged on the substrate 101 to be spaced apart from each other in the first horizontal direction (X direction), the second horizontal direction (Y direction), and the third horizontal direction (Z direction). For example, a cell capacitor CAP may be arranged between transistor bodies 220 spaced apart from each other in the first horizontal direction (X direction), or a second buried insulating layer 196 and a bit line BL may be arranged therebetween. For example, the plurality of transistor bodies 220 may be spaced apart from each other in the second horizontal direction (Y direction) with a first buried insulating layer 162 therebetween. For example, the plurality of transistor bodies 220 may be spaced apart from each other in a vertical direction (Z direction) with an isolation insulating pattern 154 therebetween.

In some embodiments, the second buried insulating layer 196 and the first buried insulating layer 162 may include any one of a silicon oxide, a silicon oxynitride, a carbon-containing silicon oxide, a carbon-containing silicon nitride, and a carbon-containing silicon oxynitride, but are not limited to the examples.

According to some embodiments, one end of each of the plurality of transistor bodies 220 in the first horizontal direction (X direction) may be connected in contact with the bit line BL, and the other end in the first horizontal direction (X direction) may be connected in contact with the cell capacitor CAP. According to some embodiments, at least some portions of both surfaces of each of the plurality of transistor bodies 220 in the vertical direction (Z direction) may be covered or overlapped by the word lines WL, respectively.

In some embodiments, the plurality of transistor bodies 220 may include an undoped semiconductor material and/or a doped semiconductor material. For example, the plurality of transistor bodies 220 may include polysilicon.

In some embodiments, the plurality of transistor bodies 220 may include an amorphous metal oxide, a polycrystalline metal oxide, a combination of an amorphous metal oxide and a polycrystalline metal oxide, or the like. For example, the plurality of transistor bodies 220 may include at least one of an In-Ga-based oxide (IGO), an In-Zn-based oxide (IZO), or an In-Ga-Zn-based oxide (IGZO).

According to some embodiments, each of the plurality of transistor bodies 220 may include a first source/drain region 222, a single crystal channel layer 224, and a second source/drain region 226. For example, the single crystal channel layer 224 may be arranged between the first source/drain region 222 and the second source/drain region 226 in the first horizontal direction (X direction).

The first source/drain region 222 may be connected to and be in contact with the bit line BL, and the second source/drain region 226 may be connected to the cell capacitor CAP and be in contact with the first electrode EL1. Both ends of the single crystal channel layer 224 in the first horizontal direction (X direction) may contact the first source/drain region 222 and the second source/drain region 226, respectively. In some embodiments, the first source/drain region 222 and the second source/drain region 226 may each include a semiconductor material doped with high concentrations of n-type dopants. In some embodiments, the single crystal channel layer 224 may comprise a single crystal semiconductor material, such as Si, SiGe, SiGeC, or SiC.

In some embodiments, both sides of the single crystal channel layer 224 in the vertical direction (Z direction) may contact respective word lines WL. In this case, the cell transistor CTR may have a double gate shape in which a word line pair WLP composed of a pair of word lines WLPs are in contact with one single crystal channel layer 224. In some other embodiments, the cell transistor CTR may have a gate-all-around shape in which one word line WL covers, overlaps, or is on both sides of the single crystal channel layer 224 in the vertical direction (Z direction) and both sides of the second horizontal direction (Y direction).

Referring to FIGS. 2A to 2D, each of the plurality of word lines WL may include a first portion PP1 overlapping the plurality of single crystal channel layers 224, and a second portion PP2 extending in the second horizontal direction (Y direction) between two adjacent first portions PP1. In some embodiments, the first horizontal width W1 of the first portion PP1 in the first horizontal direction (X direction) may be greater than the second horizontal width W2 of the second portion PP2 in the first horizontal direction (X direction).

In some embodiments, the first portions PP1 of the word line pair WLP may be spaced apart from each other with the single crystal channel layer 224 and the gate dielectric layer 182 therebetween in the vertical direction (Z direction). In some embodiments, the second portions PP2 of the word line pair WLP may be spaced apart from each other with the first buried insulating layer 162 and the gate dielectric layer 182 therebetween in the vertical direction (Z direction). In some embodiments, the plurality of word line pairs WLP may be spaced apart from each other with a plurality of isolation insulating patterns 154 therebetween. In some embodiments, both surfaces of the second portion PP2 of each of the plurality of word lines WL in the first horizontal direction (X direction) may be covered with or overlapped by the first buried insulating layer 162. In some embodiments, the second portion PP2 of the plurality of word lines WL may be covered with or overlapped by the isolation insulating pattern 154 and the first buried insulating layer 162 in the vertical direction (Z direction).

In some embodiments, the horizontal width of the plurality of word lines WL in the horizontal direction (X direction and/or Y direction) may be constant regardless of the vertical levels. For example, the width of the first word line WL arranged closest to the top surface of the substrate 101 according to the first horizontal direction (X direction) may be the same as the width of the second word line WL arranged at a higher vertical level than the first word line WL according to the first horizontal direction (X direction).

In some embodiments, both side surfaces, in the first horizontal direction, of the plurality of word lines WL arranged in the vertical direction (Z direction) may be substantially perpendicular to the top surface of the substrate 101. For example, the plane areas of the plurality of word lines WL arranged in the vertical direction (Z direction) are all the same regardless of the vertical levels, and may be substantially completely vertically overlapped.

The word lines WL of the semiconductor memory device according to a comparative example have different horizontal widths according to vertical levels. For example, the word lines WL of the comparative example may have a wider horizontal width as it approaches the top surface of the substrate 101. In this case, there may be a problem in that the reliability of the semiconductor memory device is deteriorated due to a deviation in the cell transistors CTR due to the vertical levels. In some embodiments, the width of the semiconductor memory device 10 of the plurality of word lines WL according to the horizontal direction (X direction and/or Y direction) may be constant regardless of the vertical levels (i.e., distance from the substrate), and thus the operation reliability of the semiconductor memory device 10 may be improved.

According some embodiments, a plurality of bit lines BL may extend along the vertical direction (Z direction) on the substrate 101 and may be spaced apart from each other in the horizontal direction. For example, each of the plurality of bit lines BL may be connected to a first group arranged in the vertical direction (Z direction) among the plurality of cell transistors CTR.

According to some embodiments, the plurality of word lines WL may extend along the second horizontal direction (Y direction) on the substrate 101, and may be spaced apart from each other in the vertical direction (Z direction) and the first horizontal direction (X direction). For example, the plurality of word lines WL may be spaced apart from each other in the vertical direction (Z-direction) with the isolation insulating pattern 154 therebetween, and may be connected to a second group arranged in the second horizontal direction (Y-direction) among the plurality of cell transistors CTR. In some embodiments, the second group of cell transistors CTR may be spaced apart from each other in the second horizontal direction (Y direction) with the first buried insulating layer 162 therebetween.

In some embodiments, the plurality of bit lines BL and the plurality of word lines WL may each independently include at least one of a doped semiconductor material (doped silicon, doped germanium, etc.), a conductive metal nitride (titanium nitride, tantalum, etc.), a metal (tungsten, titanium, tantalum, etc.), and/or a metal-semiconductor compound (tungsten silicide, cobalt silicide, titanium silicide, etc.).

According to some embodiments, the gate dielectric layers 182 may be arranged between the plurality of word lines WL and the plurality of transistor bodies 220. The gate dielectric layer 182 may have a uniform thickness, and may have a conformal structure.

In some embodiments, the gate dielectric layer 182 may include at least one selected from a high-k dielectric material having a higher dielectric constant than silicon oxide and a ferroelectric material. For example, the gate dielectric layer 182 includes at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), tantalum strontium bismuth (STB), bismuth iron oxide (BFO), strontium titanium oxide (SrTiO), yttrium oxide (YO), aluminum oxide (AlO), or lead scandium tantalum oxide (PbScTaO). The terms “HfO,” “HfSi,” and “LaO” used in the present specification refer to materials formed of elements included in each term, and are not chemical formulas representing a stoichiometric relationship.

According to some embodiments, the plurality of word lines WL may be spaced apart from the plurality of bit lines BL in the first horizontal direction (X direction) with a plurality of capping spacers 192 therebetween. For example, each of the plurality of capping spacers 192 comes into contact with one end of each of the plurality of word lines WL in the first horizontal direction (X direction), and may at least partially vertically overlap the first source/drain region 222. According to some embodiments, the first source/drain region 222 may be spaced apart from the plurality of capping spacers 192 with the gate dielectric layer 182 therebetween. In some embodiments, both surfaces of each of the plurality of capping spacers 192 in the vertical direction (Z direction) may be covered or overlapped by the gate dielectric layers 182. In some embodiments, the plurality of capping spacers 192 may include any one of a silicon oxide, a silicon oxynitride, a carbon-containing silicon oxide, a carbon-containing silicon nitride, and/or a carbon-containing silicon oxynitride.

According to some embodiments, the plurality of word lines WL may be spaced apart from the first electrode EL1 of each of the plurality of cell capacitors CAP in the first horizontal direction (X direction) with a plurality of buried spacers 174 therebetween. According to some embodiments, the gate dielectric layers 182 may be arranged between the plurality of buried spacers 174 and the plurality of word lines WL. In some embodiments, the plurality of buried spacers 174 may at least partially vertically overlap the second source/drain region 226. According to some embodiments, both surfaces of the plurality of buried spacers 174 in the vertical direction (Z direction) may be covered or overlapped by spacer liners 172, and the second source/drain region 226 may be spaced apart from the plurality of buried spacers 174 in the vertical direction (Z direction) with the spacer liner 172 therebetween. In some embodiments, the spacer liners 172 may be made of silicon nitride, and the plurality of buried spacers 174 may include any one of a silicon oxide, silicon oxynitride, carbon-containing silicon oxide, carbon-containing silicon nitride, and/or carbon-containing silicon oxynitride.

In some embodiments, the plurality of capping spacers 192 and the plurality of buried spacers 174 may be arranged at the same vertical levels with respect to the substrate as the plurality of word lines WL.

In some embodiments, a plurality of isolation insulating patterns 154 may be arranged between a plurality of cell transistors CTR spaced apart from each other in the vertical direction (Z direction). For example, the plurality of isolation insulating patterns 154 may be arranged between two word lines WL spaced apart from each other in the vertical direction (Z direction).

In some embodiments, the gate dielectric layers 182 may be arranged between the plurality of isolation insulating patterns 154 and the plurality of word lines WL. In some embodiments, the gate dielectric layers 182 may be arranged between the plurality of isolation insulating patterns 154 and the plurality of capping spacers 192. In some embodiments, the spacer liners 172 may be arranged between the plurality of isolation insulating patterns 154 and the plurality of buried spacers 174.

According to some embodiments, the first electrodes EL1 of each of the plurality of cell capacitors CAP may be connected to the second source/drain region 226. The first electrode EL1 may have a cup shape having a side surface parallel to the first horizontal direction (X direction) and a bottom surface perpendicular to the first horizontal direction (X direction). For example, as illustrated in FIGS. 2B and 2C, the first electrode EL1 may have a U-shaped horizontal cross section rotated by 90 degrees with respect to the top surface of the substrate such that the side surface of the first electrode EL1 is parallel to the top surface of the substrate.

According to some embodiments, a capacitor dielectric layer DL may cover or overlap a surface of the first electrode EL1. The capacitor dielectric layer DL may have a uniform thickness. Accordingly, the capacitor dielectric layer DL may have a conformal shape. The second electrode EL2 may be spaced apart from the first electrode EL1 with the capacitor dielectric layer DL therebetween.

In some embodiments, among a plurality of memory cells, a sub-memory cell array repeatedly arranged in the second horizontal direction (Y direction) and the vertical direction (Z direction) may share one second electrode EL2. In some embodiments, a first sub-cell array and a second sub-cell array may be symmetrically arranged with the second electrode EL2 therebetween. In this case, the first sub-cell array and the second sub-cell array may share the second electrode EL2.

In some embodiments, the first sub-cell array and the second sub-cell array sharing one second electrode EL2 may include a first memory cell group. In some embodiments, the first memory cell group may be spaced apart from a second memory cell group with a second buried insulating layer 196 therebetween. For example, a plurality of memory cell groups may be arranged to be spaced apart from each other in the first horizontal direction (X direction).

Referring to FIG. 2D, in some embodiments, the second buried insulating layer 196 may extend in the vertical direction (Z direction) on the substrate 101. In some embodiments, the horizontal width of the second buried insulating layer 196 in the first horizontal direction (X direction) may increase as it is away from the top surface of the substrate 101 in the vertical direction (Z direction). For example, the second buried insulating layer 196 may have a tapered shape in which the horizontal width becomes narrower as it approaches the substrate 101 in the vertical direction (Z direction). In some embodiments, the sidewall of the second buried insulating layer 196 may have an inclination with respect to the top surface of the substrate 101.

In some embodiments, the second buried insulating layer 196 may be in contact with the first buried insulating layer 162 in the first horizontal direction (X direction). For example, one side surface of the first buried insulating layer 162 may have a downward slope, and may be covered with or overlapped by the second buried insulating layer 196. In some embodiments, the other side surface of the first buried insulating layer 162 in the first horizontal direction (X direction) may come in contact with the second electrode EL2 with the capacitor dielectric layer DL therebetween. In some embodiments, the other side surface of the first buried insulating layer 162 may have a downward slope. In some embodiments, the second electrode EL2 of the cell capacitor CAP may extend in the vertical direction (Z direction) on the substrate 101, and the horizontal width of the second electrode EL2 in the first horizontal direction (X direction) may increase as the distance from the top surface of the substrate 101 increases.

In some embodiments, the first electrodes EL1 of the plurality of cell capacitors CAP may be spaced apart from each other in the vertical direction (Z direction) with an intermediate insulating pattern 292 therebetween. In some embodiments, one side surface of each of the plurality of isolation insulating patterns 154 in the first horizontal direction (X direction) may contact the plurality of intermediate insulating patterns 292. In this case, the other side surface of each of the plurality of isolation insulating patterns 154 in the first horizontal direction (X direction) may be in contact with the bit line BL. In some embodiments, the plurality of intermediate insulating patterns 292 may be spaced apart from the second electrode EL2 with the capacitor dielectric layer DL therebetween. In some embodiments, the plurality of intermediate insulating patterns 292 may include silicon oxide, but are not limited thereto.

According to some embodiments, the first electrode EL1 and the second electrode EL2 may include a doped semiconductor material, a conductive metal nitride, such as titanium nitride, tantalum nitride, niobium nitride, or tungsten nitride, a metal, such as ruthenium, iridium, titanium, or tantalum, or a conductive metal oxide, such as an iridium oxide or niobium oxide.

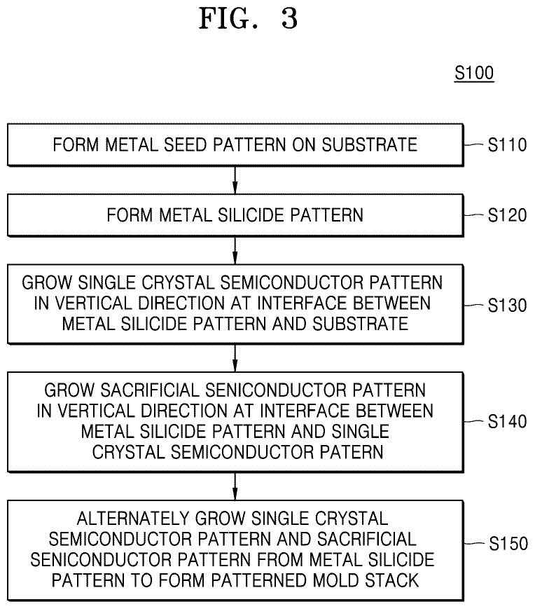

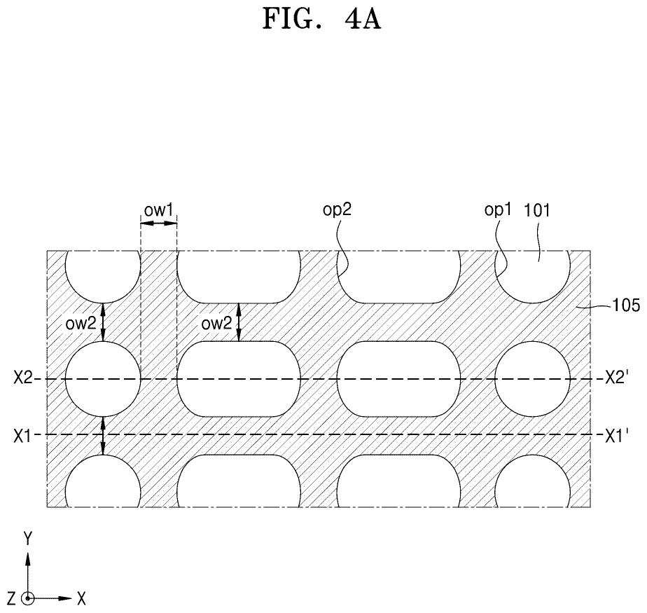

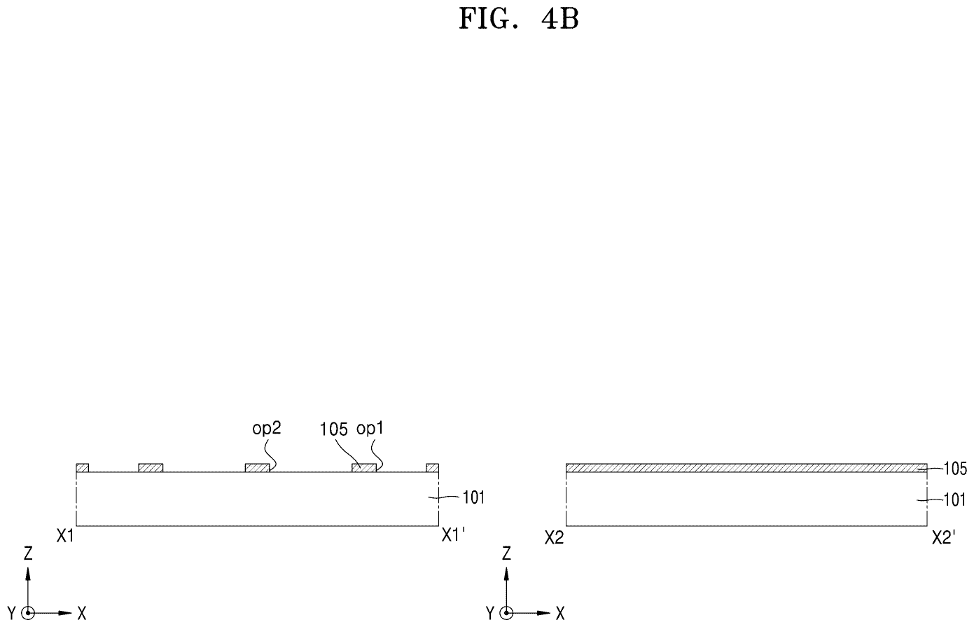

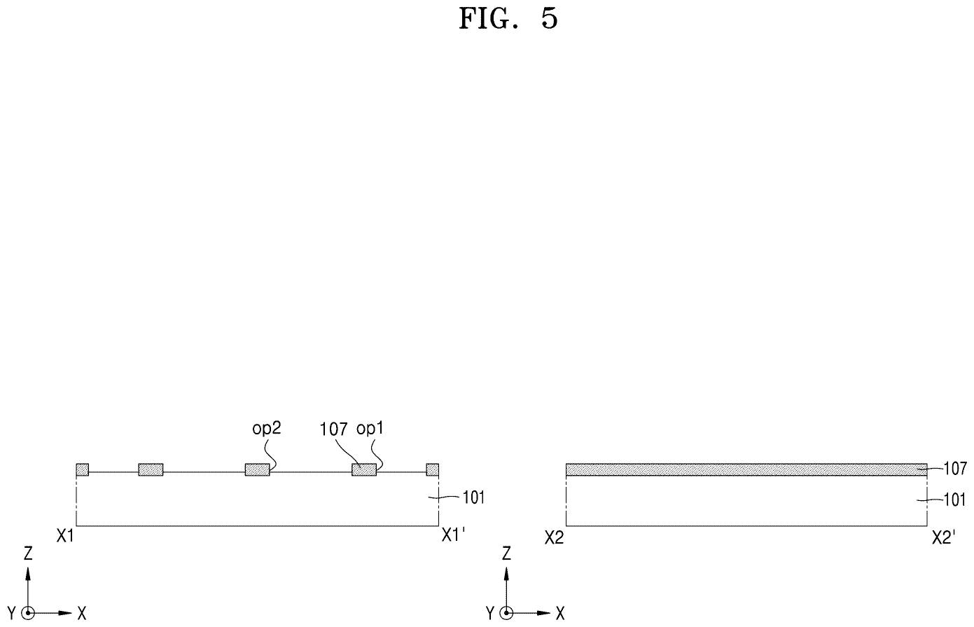

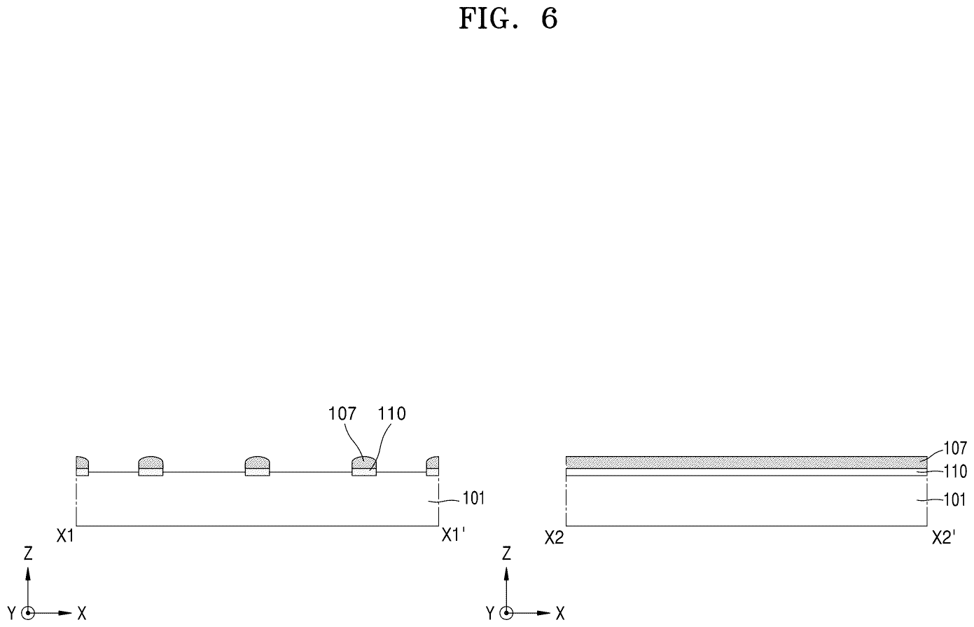

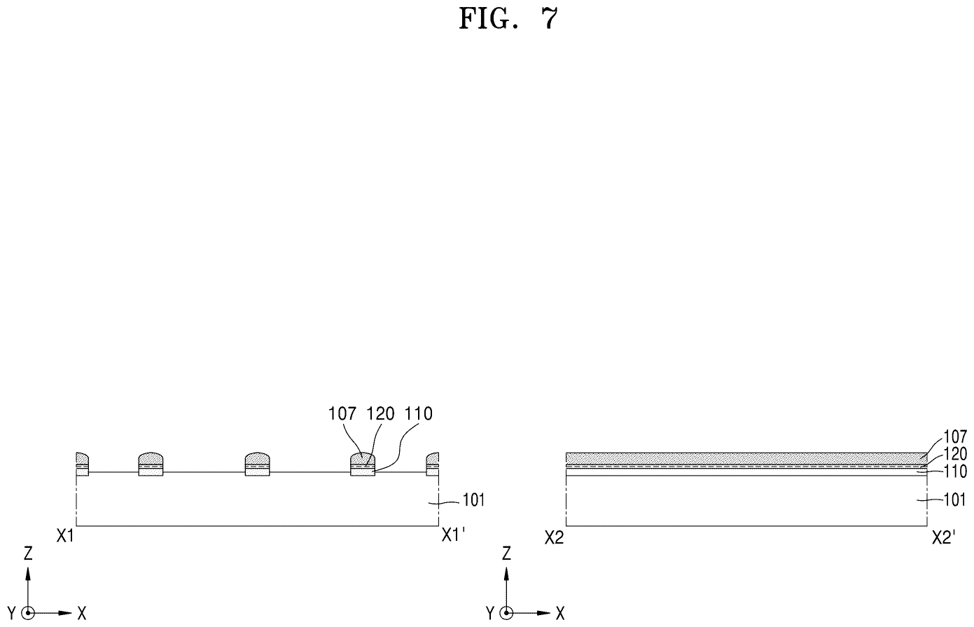

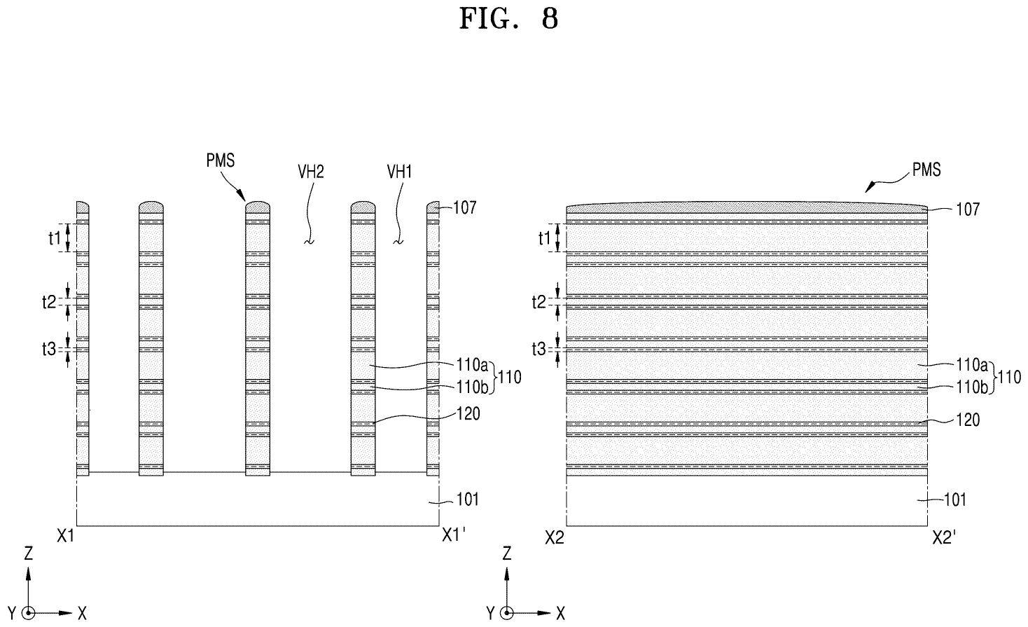

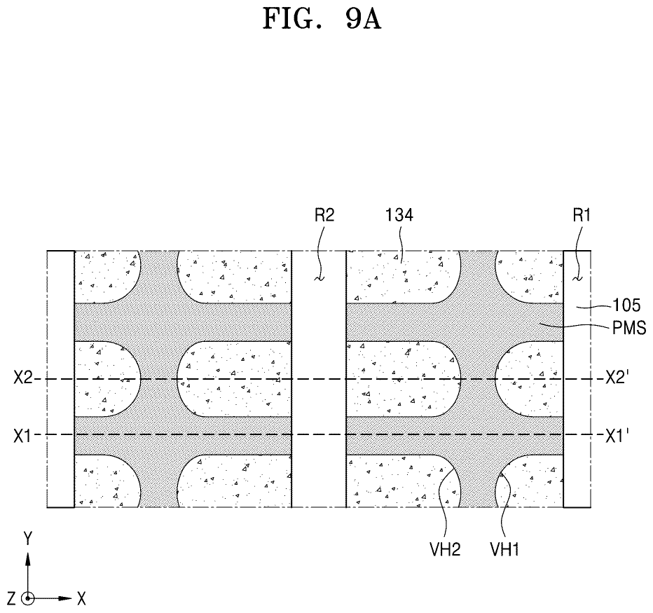

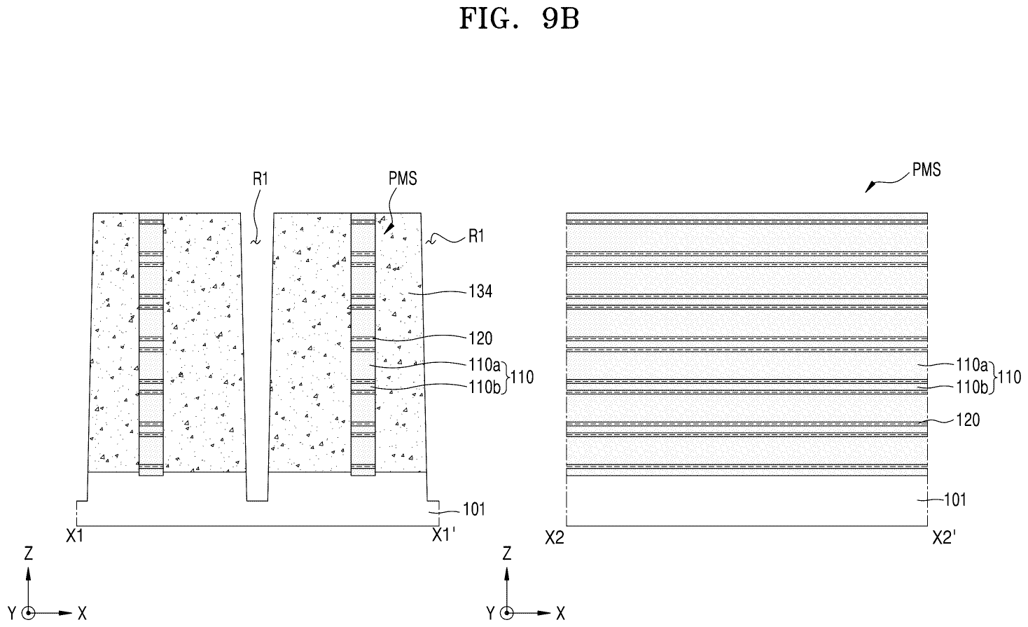

FIG. 3 is a flowchart illustrating a method of manufacturing a semiconductor memory device (S100) according to some embodiments. FIGS. 4A, 9A, 10A, and 14A are plan views for describing a method of manufacturing a semiconductor memory device according to some embodiments, and FIGS. 4B, 5, 6, 7, 8, 9B, 10B, 11, 12, 13, 14B, 15, 16, 17, 18, and 19 are cross-sectional views for describing a method of manufacturing a semiconductor memory device according to some embodiments. Specifically, FIGS. 4A, 9A, 10A, and 14A are plan views showing a top surface of a region corresponding to FIG. 2A, and FIGS. 4B, 5, 6, 8, 9b, 10b, 11, 12, 13, 14b, 15, 16, 17, 18, and 19 show parts corresponding to cross sections taken along lines X1-X1′ and X2-X2′ of FIG. 2A. Hereinafter, a method of manufacturing a semiconductor memory device will be described with reference to the flowchart of FIG. 3.

Referring to FIGS. 3, 4A, and 4B, a metal seed pattern 105 may be formed on a top surface of a substrate 101 (S110).

In some embodiments, the substrate 101 may include a single crystal semiconductor material. For example, the substrate 101 may include a semiconductor material, such as Si or Ge.

In some embodiments, the metal seed pattern 105 may be formed by depositing a metal seed layer (not shown) on the top surface of the substrate 101 by a method such as physical vapor deposition (PVD) and then removing a portion of the metal seed layer (not shown). For example, a method of forming a pattern mask (not shown) on the metal seed layer (not shown) to remove the rest except for a portion covered or overlapped by the mask (not shown) through a strip process may be used.

In some embodiments, the metal seed pattern 105 may have a plurality of first openings op1 and a plurality of second openings op2 exposing a top surface of the substrate 101.

In some embodiments, the plurality of first openings op1 and the plurality of second openings op2 may have different widths according to the first horizontal direction (X direction). For example, the plurality of second openings op2 may each have an elliptical planar shape having a long axis in the first horizontal direction (X-direction) and a short axis in the second horizontal direction (Y-direction), or a rectangular planar shape having a width in the first horizontal direction (X-direction) greater than a width in the second horizontal direction (Y-direction).

In some embodiments, the plurality of first openings op1 may have widths in the first horizontal direction (X direction) less than the plurality of second openings op2. For example, the plurality of first openings op1 may have a circular, oval, or square planar shape, but are not limited thereto.

In some embodiments, the plurality of first openings op1 and the plurality of second openings op2 may have the same horizontal widths in the second horizontal direction (Y direction).

In some embodiments, a first opening width ow1, which is the minimum width between the first opening op1 and the second opening op2 adjacent to each other in the first horizontal direction (X direction), may have a value less than a second opening width ow2, which is the minimum width between two first openings op1 adjacent to each other in the second horizontal direction (Y direction), and/or between two second openings op2 adjacent to each other in the second horizontal direction (Y direction).

In some embodiments, the plurality of first openings op1 may be arranged to be spaced apart from each other in the horizontal direction (X direction and/or Y direction). In some embodiments, the plurality of first openings op1 may be continuously arranged in the second horizontal direction (Y direction). In some embodiments, two second openings op2 may be arranged between two adjacent first openings op1 in the first horizontal direction (X direction) among the plurality of first openings op1. For example, two second openings op2 and one first opening op1 arranged continuously in the first horizontal direction (X direction) may include a first sub-opening array. The metal seed pattern 105 may have a pattern in which the first sub-opening array is repeatedly arranged in the first horizontal direction (X direction) and the second horizontal direction (Y direction).

In some embodiments, the metal seed pattern 105 may include a portion extending in the first horizontal direction (X direction) between the plurality of first openings op1 and the plurality of second openings op2, or a portion extending in the second horizontal direction Y therebetween.

In some embodiments, the metal seed pattern 105 may include gold (Au), aluminum (Al), silver (Ag), zinc (Zn), titanium (Ti), palladium (Pd), nickel (Ni), cobalt (Co), iron (Fe), indium (In), tungsten (W), and/or combinations thereof.

In some embodiments, the metal seed pattern 105 may have a first vertical thickness in the vertical direction (Z direction). According to some embodiments, the first vertical thickness may be about 0.01 nm to about 10 nm.

Referring to FIGS. 3 and 5, a metal silicide pattern 107 may be formed from the metal seed pattern 105 from the result of FIGS. 4A and 4B (S120). In some embodiments, the metal silicide pattern 107 may be formed in a temperature range of about 500° C. to about 1500° C.

For example, the metal seed pattern 105 and some of the substrate 101 in contact with the metal seed pattern 105 may move and interact with each other by diffusion to form the metal silicide pattern 107.

In some embodiments, the bottom surface of the metal silicide pattern 107 may be arranged at a lower vertical level of the top surface of the substrate 101. In some embodiments, the metal silicide pattern 107 may include at least one of silicon (Si) and/or germanium (Ge) and/or a metal.

Referring to FIGS. 3 and 6, in the result of FIG. 5, a single crystal semiconductor pattern 110 may be formed on a region of the top surface of the substrate 101 vertically overlapping the metal silicide pattern 107 (S130).

In some embodiments, the single crystal semiconductor pattern 110 may be formed by exposing the metal silicide pattern 107 to a first reaction gas under a first process temperature. In some embodiments, the metal silicide pattern 107 may be melted at the first process temperature to form a first eutectic layer.

In some embodiments, the first reaction gas may include a first precursor source. In some embodiments, the first precursor source may include a Si source for forming the single crystal semiconductor pattern 110. For example, the Si source may include at least one selected from silane (SiH₄), disilane (Si₂H₆), trisilane (Si₃H₈), and/or dichlorosilane (SiH₂Cl₂).

According to some embodiments, the first eutectic layer may be a metal-semiconductor material eutectic layer. In some embodiments, the first eutectic layer may be a gold (Au)-silicon (Si) eutectic layer.

In some embodiments, the first eutectic layer may serve as a catalyst in the formation reaction of the single crystal semiconductor pattern 110. The first precursor source may contact and react with a molten metal silicide pattern 107 (e.g., a first eutectic layer) to form a first source atom (e.g., Si atom) in the first eutectic layer, and the first source atom may penetrate into the first eutectic layer to form the single crystal semiconductor pattern 110 at an interface between the first eutectic layer and the substrate 101.

In some embodiments, the single crystal semiconductor pattern 110 may be grown on a bottom surface of the first eutectic layer. For example, the single crystal semiconductor pattern 110 may grow in a direction away from the top surface of the substrate 101, that is, a vertical direction (Z direction) at the interface between the first eutectic layer and the substrate 101. For example, the single crystal semiconductor pattern 110 may be formed by growing a preliminary semiconductor material layer on the top surface of the substrate 101 and then further growing a semiconductor material at the interface between the preliminary semiconductor material layer and the first eutectic layer, that is, on the bottom surface of the first eutectic layer. For example, the single crystal semiconductor pattern 110 may be formed of single crystal silicon Si.

In some embodiments, a ratio of the number of metal atoms to the total number of atoms in the first eutectic layer may be about 0.05 to about 0.5, about 0.1 to about 0.4, about 0.1 to about 0.3, or about 0.1 to about 0.25. In some embodiments, a ratio of silicon (Si) atoms to the total number of atoms in the first eutectic layer may be about 0.6 to about 0.99, about 0.7 to about 0.95, or about 0.8 to about 0.95. When the content of metal atoms in the first eutectic layer is too much, the growth rate of the single crystal semiconductor pattern 110 may decrease, and thus pattern imbalance may occur according to growth in the horizontal direction (X direction and/or Y direction). When the content of silicon atoms in the first eutectic layer is excessively much, the temperature for forming the first eutectic layer is increased, and the growth rate of the single crystal semiconductor pattern 110 may be lowered.

In some embodiments, the first process temperature may be about 250° C. to about 1500° C. For example, when the first process temperature is too low, the metal silicide pattern 107 may not form the first eutectic layer and thus may not serve as a catalyst for forming the single crystal semiconductor pattern 110. For example, when the first process temperature is too high, the reliability of the semiconductor memory device 10 may deteriorate due to the diffusion of semiconductor atoms between adjacent substrates 101.

The first process temperature may vary according to the type and content of the metal atom and the source atom. For example, when the metal silicide pattern 107 includes gold (Au), the first process temperature may be about 250° C. to about 450° C. For example, when the metal silicide pattern 107 includes aluminum (Al), the first process temperature may be about 450° C. to about 650° C. For example, when the metal silicide pattern 107 includes silver (Ag), the first process temperature may be about 750° C. to about 950° C. For example, when the metal silicide pattern 107 includes zinc (Zu), the first process temperature may be about 350° C. to about 550° C. For example, when the metal silicide pattern 107 includes titanium (Ti), the first process temperature may be about 1250° C. to about 1450° C. For example, when the metal silicide pattern 107 includes palladium (Pd), the first process temperature may be about 750° C. to about 950° C.

In some embodiments, the substrate 101 may be configured such that the same crystal plane faces a top surface. In some embodiments, a semiconductor material obtained from the first precursor source may grow in a single crystal epitaxial growth on the substrate 101, and the single crystal semiconductor pattern 110 may have a constant crystal plane direction and may grow uniformly in the vertical direction (Z direction). For example, the single crystal semiconductor pattern 110 may have a uniform vertical thickness regardless of the position in the horizontal direction (X direction and/or Y direction) on the substrate 101.

In some embodiments, the metal silicide pattern 107 may be spaced apart from the substrate 101 with the single crystal semiconductor pattern 110 therebetween.

In the method of growing a single crystal semiconductor material according to a comparative example, for example, a single crystal semiconductor material epitaxially grows on the substrate 101 by chemical vapor deposition (CVD), plasma enhanced CVD (PECVD), or atomic layer deposition (ALD) process. According to some embodiments, the epitaxial growth rate using the metal silicide pattern 107 may be about 1.5 to about 1000 times faster than the growth method of the single crystal semiconductor material according to a comparative example. According to some embodiments, since the single crystal semiconductor pattern 110 epitaxially grows between the substrate 101 and the metal silicide pattern 107, the pattern imbalance problem due to a difference in growth speed according to the crystal plane may be reduced. For example, the single crystal semiconductor pattern 110 may grow in the vertical direction (Z direction) and have a side surface perpendicular to the top surface of the substrate 101.

According to some embodiments, while growing the single crystal semiconductor pattern 110, impurities may be removed from a partial area of the substrate 101 exposed without vertically overlapping the metal silicide pattern 107.

In some embodiments, the first reaction gas may further include a first etching composition. In some embodiments, the first etching composition may serve to remove amorphous polysilicon Si deposited in the remaining regions except for the region in which the metal silicide pattern 107 is formed on the substrate 101. Under the first reaction gas, the first precursor source may react with the metal silicide pattern 107 to epitaxially grow a single crystal semiconductor material on a partial region of the substrate, for example, a region vertically overlapping the metal silicide pattern 107, and form an amorphous semiconductor layer on the top surface of the substrate 101 in another exposed region of the substrate 101 except the partial region of the substrate 101. For example, the amorphous semiconductor layer may include polysilicon Si.

In some embodiments, the first etching composition may include at least one selected from HCl, Cl₂, SF₆, HF, and/or HBr, but is not limited thereto.

The method of manufacturing a memory device according to some embodiments may remove other impurities (e.g., polysilicon Si) deposited on the substrate 101 while forming the single crystal semiconductor pattern 110. For example, the first reaction gas may include the first precursor source and the first etching composition to simultaneously form the single crystal semiconductor pattern 110 and remove surrounding impurities. A mechanism that grows some of the semiconductor material in some regions while removing the semiconductor material in other regions may be implemented through a difference in the growth rate of the semiconductor material in each region and a difference in the etching rate. For example, the rate at which a single crystal semiconductor material grows on the bottom surface of the metal silicide pattern 107 through the first precursor source may be faster than the rate at which an amorphous semiconductor material grows on the substrate 101 around the metal silicide pattern 107. For example, the growth rate of the single crystal semiconductor material may be about 50 times to about 200 times faster than the growth rate of the amorphous semiconductor material. In addition, the rate at which the amorphous semiconductor material is removed through the etching gas may be faster than the rate at which the single crystal semiconductor material is removed. For example, the rate at which the amorphous semiconductor material is removed may be about 5 times to about 50 times faster than the rate at which the single crystal semiconductor material is removed. That is, the single crystal semiconductor pattern 110 may be formed as a result of a significantly faster growth rate compared to the removal rate of the single crystal semiconductor material, and the amorphous semiconductor layer may be removed simultaneously with generation as a result of a significantly faster removal rate compared to the deposition rate of the amorphous semiconductor material. In the present specification, the amorphous semiconductor layer or the amorphous semiconductor material may be referred to as an impurity.

In some embodiments, a volume ratio of the first precursor gas to the first etching composition in the first reaction gas may be about 1 to about 5. For example, when the content of the first precursor gas is too little, there may be a problem that the amount of removal of the single crystal semiconductor pattern 110 is excessively increased. For example, when the content of the first etching composition is too little, there may be a problem in that impurities are deposited around the single crystal semiconductor pattern 110 on the top surface of the substrate 101.

Referring to FIGS. 3 and 7, in the result of FIG. 6, a sacrificial semiconductor pattern 120 may be formed on the single crystal semiconductor pattern 110 (S140).

In some embodiments, the sacrificial semiconductor pattern 120 may be formed by exposing the metal silicide pattern 107 to a second reaction gas under a second process temperature. In some embodiments, the metal silicide pattern 107 may be melted at the second process temperature to form a second eutectic layer.

In some embodiments, the second reaction gas may include a second precursor source. In some embodiments, the second precursor source may include a Si source and a Ge source for forming the sacrificial semiconductor pattern 120. For example, the Si source may include at least one selected from silane (SiH₄), disilane (Si₂H₆), trisilane (Si₃H₈), and/or dichlorosilane (SiH₂Cl₂). For example, the Ge source may include at least one selected from a germane (GeH₄), a digermane (Ge₂H₆), a trigermane (Ge₃H₈), a tetragermane (Ge₄H₁₀), and/or a dichlorogermane (Ge₂H₂Cl₂).

According to some embodiments, the first eutectic layer may be a metal-semiconductor material eutectic layer. In some embodiments, the first eutectic layer may be a gold (Au)-silicon (Si)-germanium (Ge) eutectic layer.

In some embodiments, the second eutectic layer may serve as a catalyst in the formation reaction of the sacrificial semiconductor pattern 120. The second precursor source may contact and react with the molten metal silicide pattern 107 (for example, a second eutectic layer) to generate a second source atom including a Si atom and a Ge atom in the second eutectic layer, and the second source atom may form a sacrificial semiconductor pattern 120 at an interface between the second eutectic layer and the single crystal semiconductor pattern 110.

In some embodiments, the sacrificial semiconductor pattern 120 may be grown on a bottom surface of the second eutectic layer. For example, the sacrificial semiconductor pattern 120 may grow in a direction away from the top surface of the substrate 101, that is, a vertical direction (Z direction) at the interface between the second eutectic layer and the single crystal semiconductor pattern 110. For example, the sacrificial semiconductor pattern 120 may be formed by growing a preliminary sacrificial semiconductor material layer on the top surface of the single crystal semiconductor pattern 110, and then further growing a sacrificial semiconductor material at the interface between the preliminary sacrificial semiconductor material layer and the second eutectic layer, i.e., the bottom surface of the second eutectic layer. For example, the sacrificial semiconductor pattern 120 may be formed of a single crystal silicon germanium SiGe.

In some embodiments, a ratio of the number of metal atoms to the total number of atoms in the second eutectic layer may be about 0.05 to about 0.5, about 0.1 to about 0.4, about 0.1 to about 0.3, or about 0.1 to about 0.25. In some embodiments, a ratio of the sum of the numbers of silicon (Si) atoms and germanium (Ge) atoms in the second eutectic layer may be about 0.6 to about 0.99, about 0.7 to about 0.95, or about 0.8 to about 0.95. When the content of metal atoms in the second eutectic layer is too much, the growth rate of the sacrificial semiconductor pattern 120 may decrease, and thus, pattern imbalance may occur according to growth in the horizontal direction (X direction and/or Y direction). When the content of silicon (Si) atoms and the content of germanium (Ge) atoms in the second eutectic layer is excessively much, a temperature for forming the second eutectic layer may increase and a growth rate of the sacrificial semiconductor pattern 120 may decrease.

In some embodiments, the second process temperature may be about 150° C. to about 1450° C. In some embodiments, the second process temperature may be lower than the first process temperature for growing the single crystal semiconductor pattern 110. Accordingly, a three-component second eutectic layer containing germanium (Ge) may be easily formed, and the sacrificial semiconductor pattern 120 may be rapidly grown in the vertical direction (Z direction) in the presence of the second eutectic layer.

For example, when the second process temperature is too low, the metal silicide pattern 107 may not form the second eutectic layer and thus, may not serve as a catalyst for forming the sacrificial semiconductor pattern 120. For example, when the second process temperature is too high, the reliability of the semiconductor memory device 10 may deteriorate due to the diffusion of semiconductor atoms between adjacent substrates 101. For example, the second process temperature may vary depending on the type and content of the metal atom and/or the source atom.

In some embodiments, a content of a silicon (Si) atom and a content of a germanium (Ge) atom in the second eutectic layer may be substantially the same. In some other embodiments, a content of a silicon (Si) atom and a content of a germanium (Ge) atom in the second eutectic layer may be different from each other. For example, a content of a silicon (Si) atom in the second eutectic layer may be less than a content of a germanium (Ge) atom. For example, a content of a silicon (Si) atom in the second eutectic layer may be greater than a content of a germanium (Ge) atom.

In some embodiments, the sacrificial semiconductor pattern 120 may epitaxially grow on the top surface of the single crystal semiconductor pattern 110 in the vertical direction (Z direction). In some embodiments, the sidewall profile of the sacrificial semiconductor pattern 120 may be substantially the same as the sidewall profile of the semiconductor pattern 110 (e.g., perpendicular to the top surface of the substrate 101).

In some embodiments, the second reaction gas may further include a second etching composition. The role and composition of the second etching composition are the same as those described above with respect to the first etching composition. For example, while growing the sacrificial semiconductor pattern 120, impurities may be removed from a partial area of the substrate 101 exposed without vertically overlapping the metal silicide pattern 107.

Referring to FIGS. 3 and 8, a patterned mold stack PMS may be formed by alternately performing the method of growing the single crystal semiconductor pattern 110 and the method of growing the sacrificial semiconductor pattern 120 on the result of FIG. 7 (S150).

In some embodiments, a single crystal semiconductor pattern 110 may be grown on the sacrificial semiconductor pattern 120 formed on the bottom surface of the metal silicide pattern 107 by heating the metal silicide pattern 107 to form a eutectic layer and then exposing the eutectic layer to the Si source-containing first reaction gas. In this operation, the metal silicide pattern 107 may form the first eutectic layer described above. Thereafter, the sacrificial semiconductor pattern 120 may be formed by being exposed again to the second reaction gas including the Si source and the Ge source. The patterned mold stack PMS may be formed by repeating the above process.

In some embodiments, a plurality of single crystal semiconductor patterns 110 and a plurality of sacrificial semiconductor patterns 120 may be alternately grown in the vertical direction (Z direction) so as to move away from the substrate 101 from the bottom surface of the metal silicide pattern 107.

For example, the patterned mold stack PMS may have a structure in which the plurality of single crystal semiconductor patterns 110 and the plurality of sacrificial semiconductor patterns 120 are alternately stacked one by one on the substrate 101. According to some embodiments, the patterned mold stack PMS may have a plurality of first vertical holes VH1 and a plurality of second vertical holes VH2 exposing the top surface of the substrate 101.

In some embodiments, the plurality of single crystal semiconductor patterns 110 may include a plurality of first semiconductor patterns 110a and a plurality of second semiconductor patterns 110b having different thicknesses. The plurality of first semiconductor patterns 110a and the plurality of second semiconductor patterns 110b may be alternately arranged one by one in the vertical direction (Z direction). For example, the first semiconductor pattern 110a and the second semiconductor pattern 110b may be alternately arranged on each of the plurality of sacrificial semiconductor patterns 120 spaced apart from each other in the vertical direction (Z direction).

In some other embodiments, the sacrificial semiconductor pattern 120 may be formed on the substrate 101 earlier than the single crystal semiconductor pattern 110. In this case, the patterned mold stack PMS may have a structure in which the plurality of sacrificial semiconductor patterns 120 and the plurality of single crystal semiconductor patterns 110 are sequentially stacked one by one on the substrate 101 in the vertical direction (Z direction).

In some embodiments, each of the plurality of sacrificial semiconductor patterns 120 and the plurality of single crystal semiconductor patterns 110 may have a thickness of several tens of nm. The first semiconductor pattern 110a may have a first thickness t1, the second semiconductor pattern 110b may have a second thickness t2, and the sacrificial semiconductor pattern 120 may have a third thickness t3. The first thickness t1 may be greater than the second thickness t2. In some embodiments, the first thickness t1 may have a value greater than or equal to about 10 nm than the second thickness t2. In some embodiments, the third thickness t3 may have a value less than each of the first thickness t1 and the second thickness t2.

In some other embodiments, each of the plurality of single crystal semiconductor patterns 110 may be formed to have substantially the same vertical thickness.

In some embodiments, each of the plurality of first vertical holes VH1 and the plurality of second vertical holes VH2 may have a uniform horizontal width regardless of the vertical levels with respect to substrate 101. For example, the inner walls of the plurality of first vertical holes VH1 and the inner walls of the plurality of second vertical holes VH2 may be perpendicular to the top surface of the substrate 101. For example, inner sidewalls of the patterned mold stack PMS defines the plurality of vertical holes. The inner sidewalls are perpendicular to the top surface of the substrate.

According to the method of manufacturing the semiconductor memory device 10 according to the comparative example, a mold stack is formed by repeatedly epitaxially growing a plurality of semiconductor layers and sacrificial layers on the substrate 101, and then, etching the mold stack using a patterned etching mask to form the plurality of first and second vertical holes VH1 and VH2. In the process of forming the mold stack by repeatedly stacking the plurality of semiconductor layers and sacrificial layers, as a result of stacking a plurality of large-area planes, a lattice defect may occur due to a difference in lattice constants between the first semiconductor material including the semiconductor layer and the second semiconductor material including the sacrificial layer. Accordingly, a warpage may occur due to stress caused by dislocation of atoms during epitaxial growth. In addition, the plurality of first and second vertical holes VH1 and VH2 according to the comparative example have a tapered shape in which the horizontal width narrows while approaching the substrate 101. The difference in the horizontal width according to the vertical direction (Z direction) causes a resistance deviation of the word line WL (refer to FIGS. 2A to 2D), thereby deteriorating the reliability of the semiconductor memory device 10.

In contrast, the method of manufacturing the semiconductor memory device 10 according to some embodiments may form a patterned mold stack PMS using a metal induced crystallization method using the metal silicide pattern 107. By growing the single crystal semiconductor pattern 110 and the sacrificial semiconductor pattern 120 selectively patterned on a partial area of the substrate 101, the occurrence of lattice defects due to a difference in lattice constants between the first semiconductor material and the second semiconductor material may be reduced. In addition, the single crystal semiconductor pattern 110 and the sacrificial semiconductor pattern 120 are grown in the vertical direction (Z direction), so that the first and second vertical holes VH1 and VH2 each have a uniform horizontal width regardless of the vertical levels with respect to substrate 101, so that the electrical reliability of the semiconductor memory device 10 can be improved.

Referring to FIGS. 9A and 9B together with FIG. 8, after removing the metal silicide pattern 107 from the result of FIG. 7, the sacrificial insulating layer 134 may be at least partially or fully filled in the plurality of first vertical holes VH1 and the plurality of second vertical holes VH2.

According to some embodiments, the sacrificial insulating layer 134 may include a silicon oxide, silicon oxynitride, carbon-containing silicon oxide, carbon-containing silicon nitride, carbon-containing silicon oxynitride, or a combination thereof.

Thereafter, an etching mask layer (not shown) covering or overlapping the patterned mold stack PMS and the sacrificial insulating layer 134 may be formed, and then a first recess R1 and a second recess R2 exposing the substrate 101 through the patterned mold stack PMS and the sacrificial insulating layer 134 may be formed through an anisotropic etching process. The etching mask layer (not shown) may have a plurality of openings corresponding to the first recess R1 and the second recess R2. In some embodiments, the etching mask layer (not shown) may be formed of silicon nitride.

In some embodiments, each of the first recess R1 and the second recess R2 may extend along the second horizontal direction (Y direction). In some embodiments, each of the first recess R1 and the second recess R2 may have a tapered shape in which the horizontal width becomes narrower while approaching the substrate 101.

The first recess R1 may extend in the second horizontal direction (D2 direction) over the other end opposite to the plurality of second vertical holes VH2 in both ends in the first horizontal direction (X direction) of each of the plurality of first vertical holes VH1. A portion of the first sacrificial insulating layer 134 filling the plurality of first vertical holes VH1 may be exposed on an inner side surface of the first recess R1.

The second recess R2 may extend in the second horizontal direction (Y direction) over one end of each of the two adjacent vertical holes VH2 in the first horizontal direction (X direction). A portion of the sacrificial insulating layer 134 filling the plurality of second vertical holes VH2 may be exposed on an inner side surface of the second recess R2.

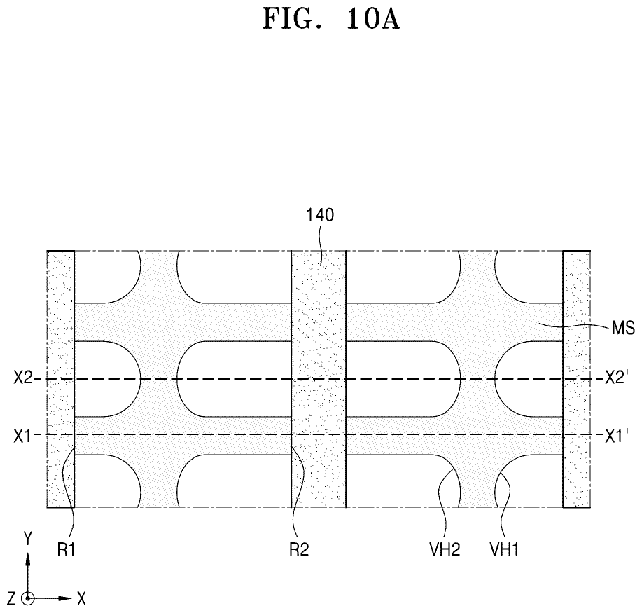

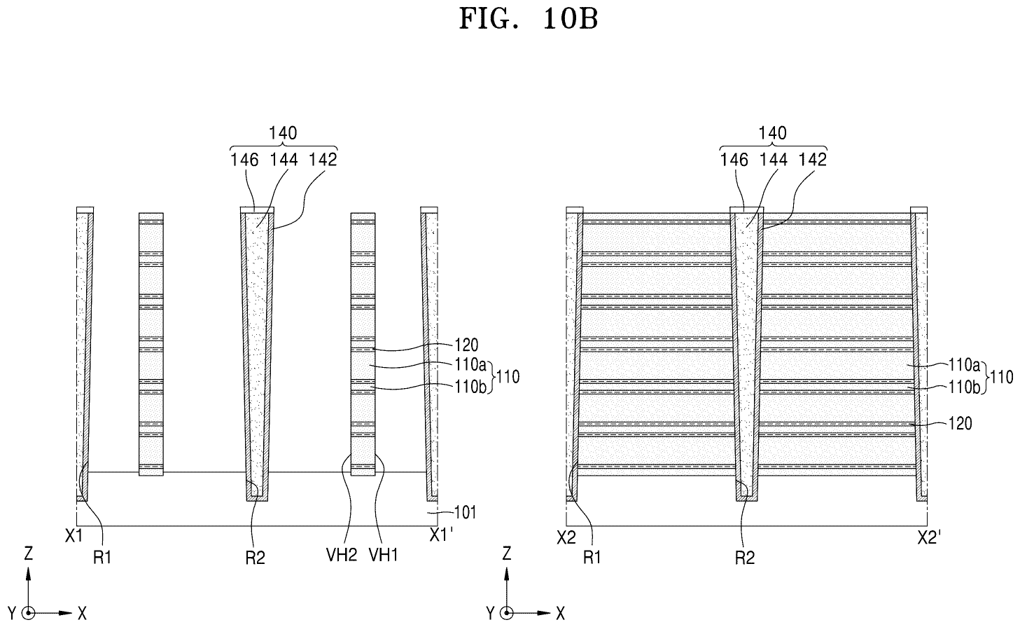

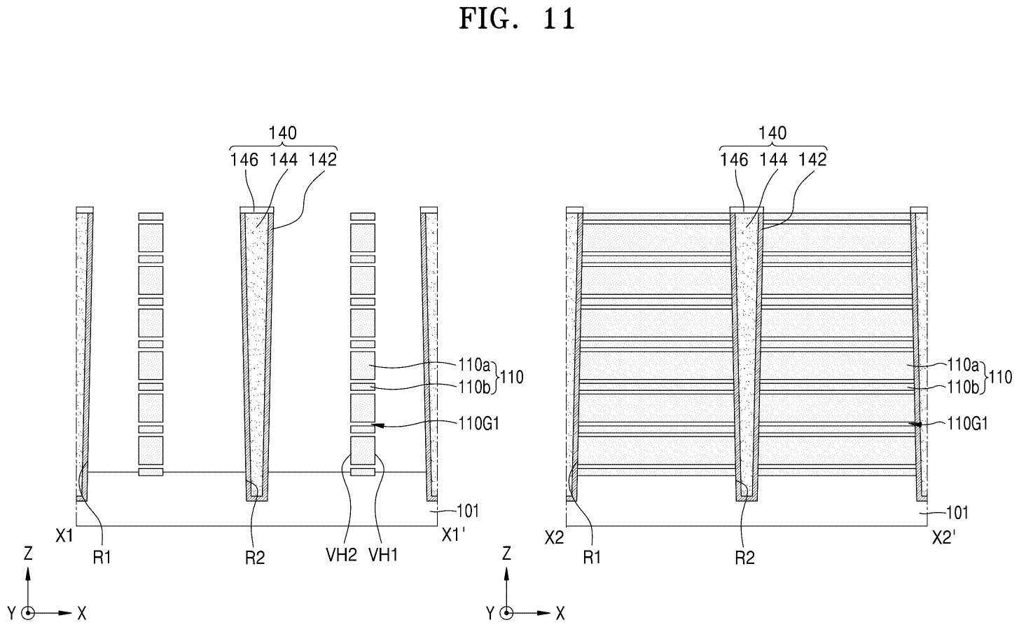

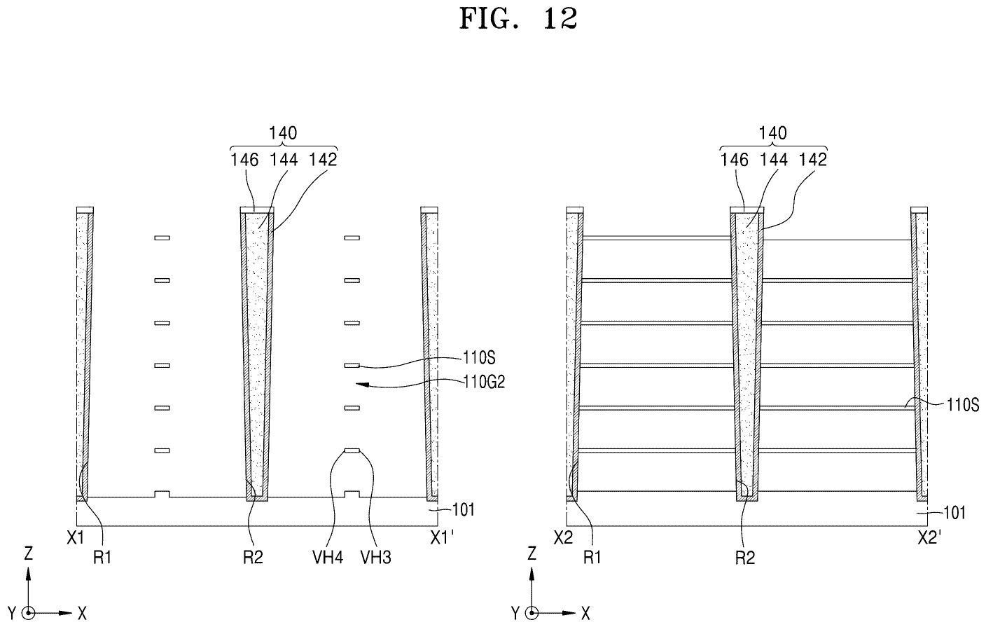

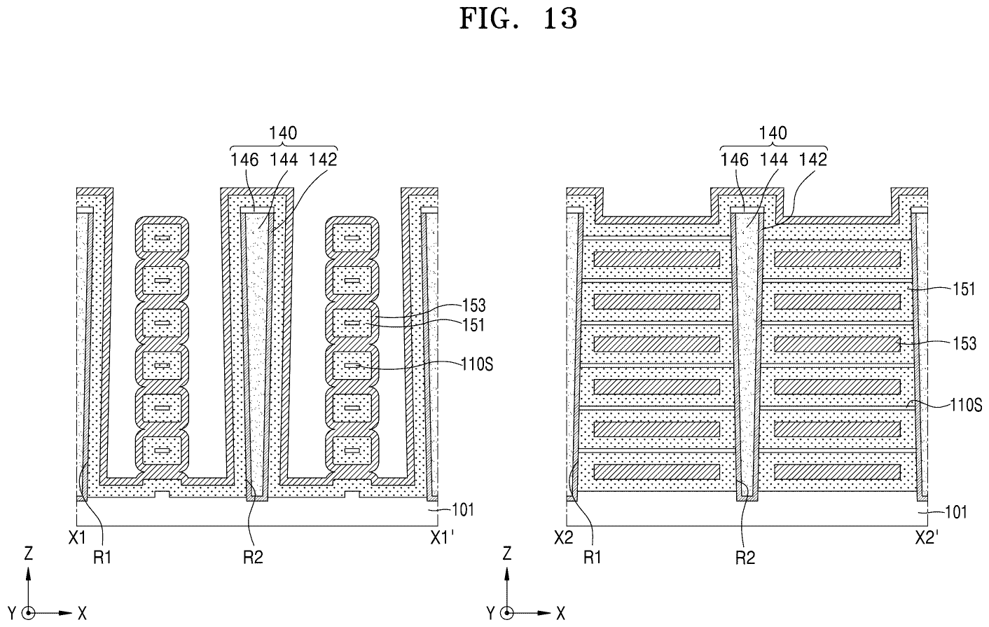

Referring to FIGS. 10A and 10B together with FIGS. 9A and 9B, after the buried structure 140 for filling the first recess R1 is formed, the etching mask layer (not shown) may be removed, and a sacrificial insulating layer 134 for filling the plurality of first vertical holes VH1 and the plurality of second vertical holes VH2 may be removed.

In some embodiments, the buried structure 140 may include a liner 142, a buried layer 144, and a capping layer 146. The liner 142 may conformally cover or overlap a bottom surface and a side surface of the first recess R1. The buried layer 144 may cover or overlap the liner 142 and at least partially or fully fill the first recess R1. The capping layer 146 may cover or overlap a top surface of the liner 142 and a top surface of the buried layer 144. In some embodiments, the liner 142 and the capping layer 146 may be formed of silicon nitride. In some embodiments, the buried layer 144 may include any one of a silicon oxide, a silicon oxynitride, a carbon-containing silicon oxide, a carbon-containing silicon nitride, and/or a carbon-containing silicon oxynitride.

Referring to FIG. 11 together with FIGS. 10A and 10B, the plurality of sacrificial semiconductor patterns 120 are removed through the plurality of first vertical holes VH1 and the plurality of second vertical holes VH2, thereby forming a plurality of first gaps 110G1 in the vertical direction (Z direction) between the plurality of single crystal semiconductor patterns 110. The plurality of first gaps 110G1 may be formed by removing the plurality of sacrificial semiconductor patterns 120 through an isotropic etching process having etch selectivity with respect to the substrate 101, the plurality of single crystal semiconductor patterns 110, the liner 142, and the capping layer 146.

Referring to FIG. 12, in the result of FIG. 11, portions of the plurality of single crystal semiconductor patterns 110 exposed through the plurality of first vertical holes VH1, the plurality of second vertical holes VH2, and the plurality of first gaps 110G1 may be removed to form a plurality of single crystal slits 110S. In some embodiments, each of the plurality of single crystal slits 110S may have a vertical thickness of about 5 nm to about 15 nm. For example, each of a plurality of single crystal slits 110S may have a vertical thickness of about 10 nm. The horizontal width of each of the plurality of single crystal slits 110S in the second horizontal direction (Y direction) of FIG. 12 may be formed to have a value less than the horizontal width of the plurality of single crystal semiconductor patterns 110 of FIG. 11.

In some embodiments, the plurality of single crystal slits 110S may be formed by removing a portion of the plurality of single crystal semiconductor patterns 110 through an isotropic etching process having etch selectivity with respect to the liner 142 and the capping layer 146. In some embodiments, in the process of forming the plurality of single crystal slits 110S, a portion of the substrate 101 exposed to the bottom surfaces of the plurality of first vertical holes VH1 and the plurality of second vertical holes VH2 may also be removed.

In some embodiments, the plurality of single crystal semiconductor patterns 110 may be made of the same material as the substrate 101, and in FIG. 12, the semiconductor pattern 110 formed at the lowermost layer among the plurality of single crystal semiconductor patterns 110 and contacting the substrate 101 is a portion of the substrate 101 and has a structure protruding from the top surface of the substrate 101.

In some other embodiments, the plurality of single crystal semiconductor patterns 110 may be formed of a material different from the substrate 101.

In some embodiments, when the plurality of single crystal semiconductor patterns 110 include the plurality of first semiconductor patterns 110a and the plurality of second semiconductor patterns 110b having different thicknesses, all of the plurality of second semiconductor patterns 110b having a relatively less thickness are removed, and only a portion of the plurality of first semiconductor patterns 110a may remain as the plurality of single crystal slits 110S. In some other embodiments, when each of the plurality of single crystal semiconductor patterns 110 has substantially the same thickness, a portion of each of the plurality of single crystal semiconductor patterns 110 may all remain as the plurality of single crystal slits 110S.

In some embodiments, the plurality of single crystal slits 110S are arranged at different vertical levels with respect to substrate 101, and may overlap each other in the vertical direction (Z direction).

In some embodiments, as illustrated in FIG. 12, each of the plurality of single crystal slits 110S may include a first part in contact with the buried structure 140 and a second part spaced apart from the buried structure 140. For example, the second part may extend in the second horizontal direction (Y direction) between two adjacent first parts in the second horizontal direction (Y direction) and may be connected to the two first parts. In some embodiments, the second parts of the plurality of single crystal slits 110S may be aligned in a line in the vertical direction (Z direction), and may be substantially completely vertically overlapped. In some embodiments, the second parts of the plurality of single crystal slits 110S may have the same horizontal width in the first horizontal direction (X direction). In some embodiments, both sidewalls of each of the second parts of the plurality of single crystal slits 110S in the first horizontal direction (X direction) may be arranged on a virtual line perpendicular to the substrate 101.

In some embodiments, the plurality of buried structures 140 may each have a tapered shape in which the horizontal width in the first horizontal direction (X direction) becomes narrower while approaching the top surface of the substrate 101. In some embodiments, the distance between the second parts of the plurality of single crystal slits 110S and the buried structure 140 in the first horizontal direction (X direction) may vary depending on the vertical levels with respect to substrate 101. For example, a first distance between the second part of the first single crystal slit 110S, which is relatively close to the substrate 101 in the vertical direction (Z direction), and the adjacent buried structure 140 may be greater than a second distance between the second part of the second single crystal slit 110S, which is relatively far from the substrate 101 in the vertical direction (Z direction), and the adjacent buried structure 140.

The plurality of first vertical holes VH1 and the plurality of second vertical holes VH2 shown in FIG. 11 may form a plurality of third vertical holes VH3 and a plurality of fourth vertical holes VH4 shown in FIG. 12, respectively, as a result of extending in the horizontal direction by partially removing the plurality of single crystal semiconductor patterns 110. The plurality of first gaps 110G1 may form a plurality of second gaps 110G2 extending in the vertical direction (Z direction) by partially removing the plurality of single crystal semiconductor patterns 110.

Referring to FIG. 13, a plurality of support insulating layers 151 covering or overlapping the surfaces of the plurality of single crystal slits 110S and a plurality of isolation insulating layers 153 covering or overlapping the surfaces of the support insulating layers 151 may be formed. The isolation insulating layer 153 may be integrally formed to cover or overlapping surfaces of the plurality of support insulating layers 151.

Each of the plurality of support insulating layers 151 may be formed to have such a thickness that portions of the support insulating layer 151 covering or overlapping each of the plurality of single crystal slits 110S may be spaced apart from each other without contacting each other in the vertical direction (Z direction). Each of the isolation insulating layers 153 covers or overlaps the surface of each of the support insulating layers 151 and may fill between portions of two support insulating layers 151 adjacent to each other in the vertical direction (Z direction) and spaced apart from each other.

In some embodiments, the support insulating layers 151 and the isolation insulating layers 153 may also be formed on each of the exposed surfaces of the substrate 101 and the exposed surfaces of the buried structure 140.

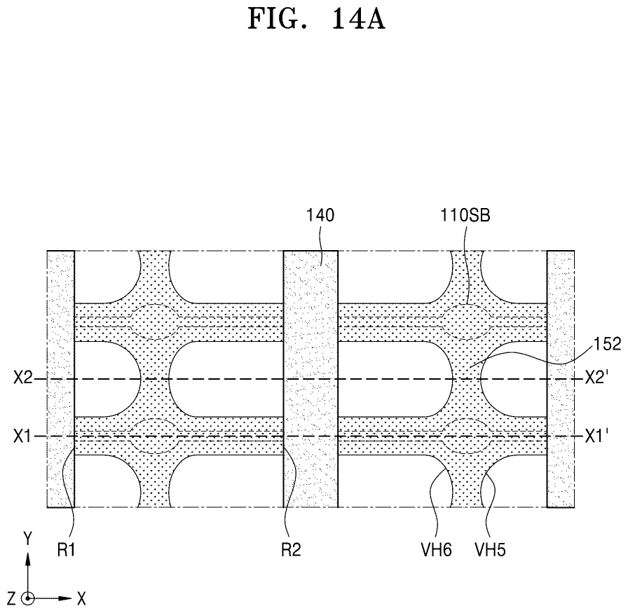

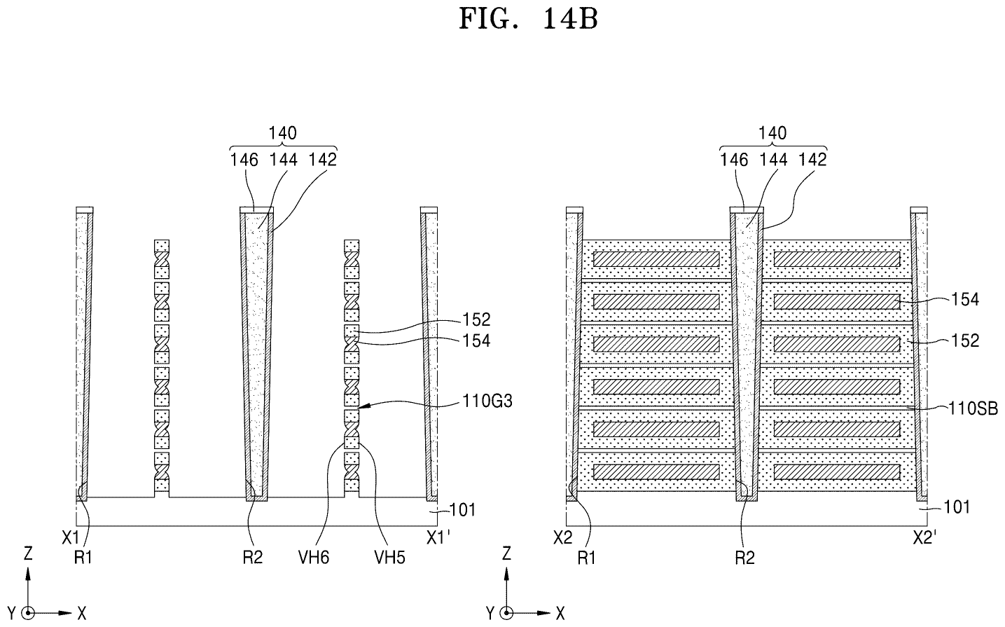

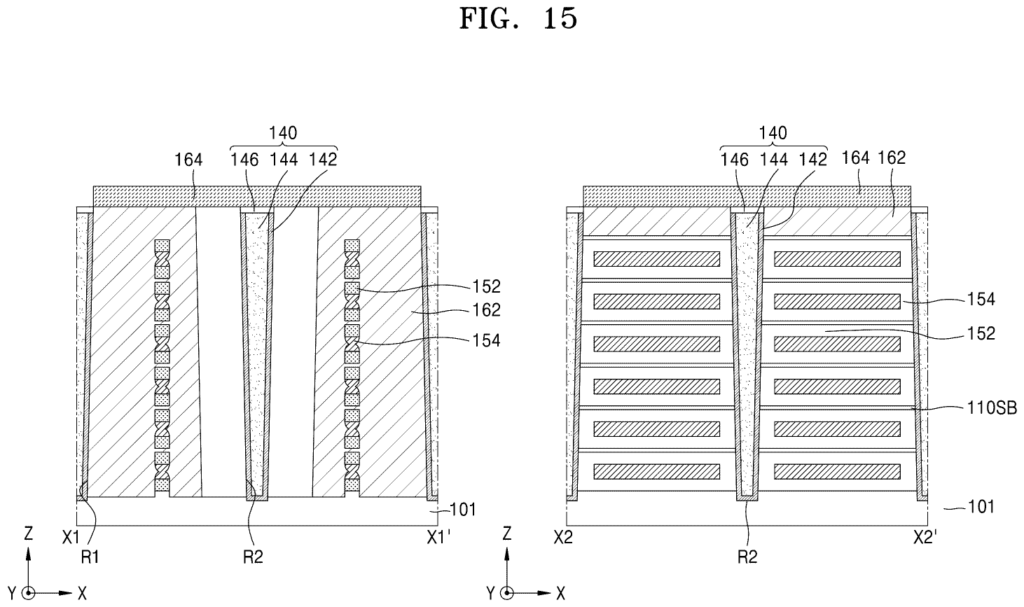

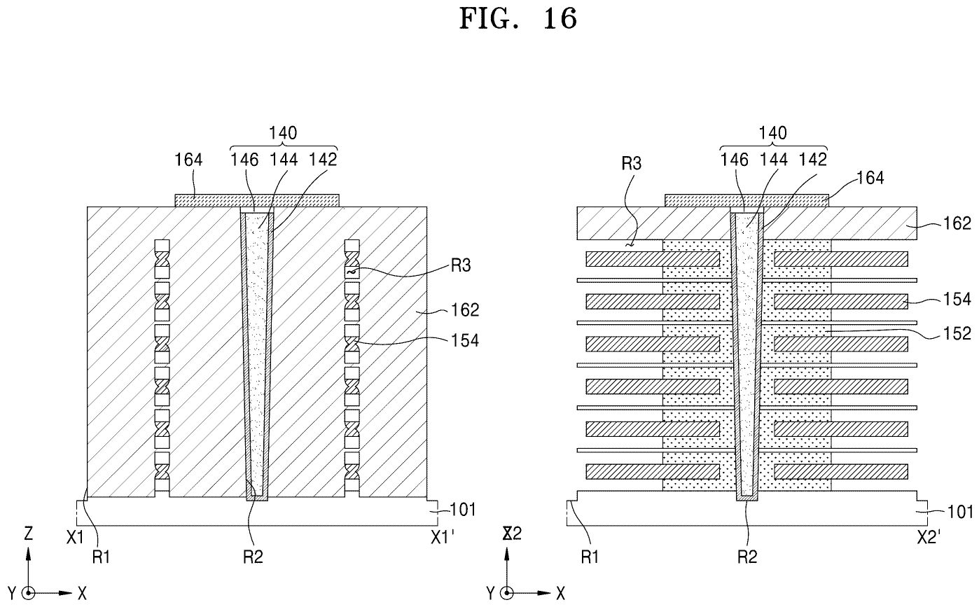

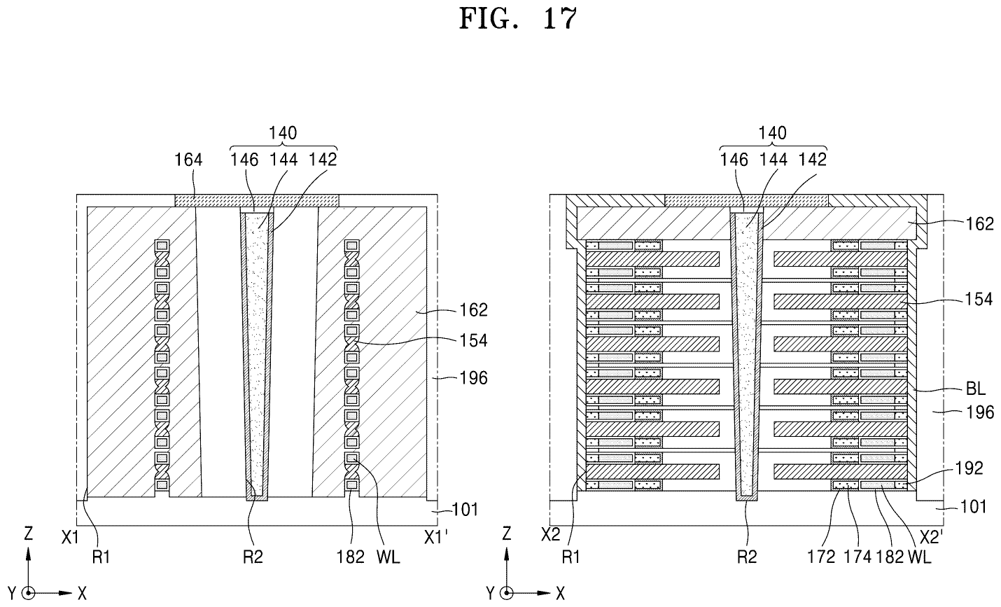

Referring to FIGS. 14A and 14B together with FIG. 13, a portion of each of the isolation insulating layers 153 may be removed to form a plurality of isolation insulating patterns 154. The plurality of isolation insulating patterns 154 may be arranged between portions of the plurality of support insulating layers 151 arranged in one row in the vertical direction (Z direction). Each of the isolation insulating patterns 154 may be formed such that the horizontal width in the first horizontal direction (X direction) has a value less than the width of each of the support insulating layers 151.

Subsequently, portions of the plurality of support insulating layers 151 may be removed to form a plurality of support patterns 152. The plurality of support patterns 152 may be arranged between the isolation insulating patterns 154 and the plurality of single crystal slits 110S.

For example, the plurality of support patterns 152 may be formed by removing the rest except for the portions of the support insulating layer 151 placed between the isolation insulating patterns 154 and the plurality of single crystal slits 110S.

Subsequently, a portion of the plurality of single crystal slits 110S may be removed to form a plurality of single crystal bars 110SB arranged between portions of two adjacent support patterns 152 between two isolation insulating patterns 154 in the vertical direction (Z direction). The plurality of single crystal bars 110SB may extend in the first horizontal direction (X direction), and may have a bar shape with substantially the same thickness in the vertical direction (Z direction).

The plurality of third vertical holes VH3 and the plurality of fourth vertical holes VH4 defined by the plurality of single crystal slits 120S shown in FIG. 12 may be a plurality of fifth vertical holes VH5 and a plurality of sixth vertical holes VH6 defined by a plurality of support patterns 152 shown in FIGS. 14A and 14B.

For example, in the process of forming the plurality of single crystal bars 110SB, the second part extending in the second horizontal direction (Y direction) and spaced apart from the buried structure 140 in the first horizontal direction (X direction) may be removed in the plurality of single crystal slits 110S illustrated in FIG. 12. A third gap 110G3 may be formed in the space from which the second portion is removed. According to some embodiments, first and second support patterns 152 adjacent to each other may be arranged between two isolation insulating patterns 154 in the vertical direction (Z direction), and the first support pattern 152 and the second support pattern 152 may be spaced apart from each other in the vertical direction (Z direction) with a third gap 110G3 therebetween.

Referring to FIG. 15, in the results of FIGS. 14A and 14B, a first buried insulation layer 162 covering or overlapping a structure obtained by stacking the plurality of single crystal bars 110SB, the plurality of support patterns 152, and the plurality of isolation insulation patterns 154 and filling the plurality of fifth vertical holes VH5, the plurality of sixth vertical holes VH6, and the plurality of third gaps 110G3, may be formed, and then a first mask layer 164 covering or overlapping the first buried insulation layer 162 and exposing at least a portion of a top surface of the buried structure 140 may be formed.

In some embodiments, the first buried insulation layer 162 may include any one of a silicon oxide, a silicon oxynitride, a carbon-containing silicon oxide, a carbon-containing silicon nitride, and/or a carbon-containing silicon oxynitride. In some embodiments, the first mask layer 164 may be made of silicon nitride.

Referring to FIG. 16, in the result of FIG. 15, the buried structure 140 filling the first recess R1 may be removed, and then a portion of the plurality of support patterns 152 may be removed through the first recess R1 to form a third recess R3.

In some embodiments, a portion of the first portions of the buried structures 140 in the first horizontal direction (X direction) of the plurality of support patterns 152, and the second portions of the plurality of support patterns 152 extending in the second horizontal direction (Y direction) and spaced apart from the buried structure 140 in the first horizontal direction (X direction) may be removed.

In some embodiments, in the process of removing a portion of the plurality of support patterns 152, a portion of the plurality of single crystal bars 110SB and a portion of the plurality of isolation insulating patterns 154 may be placed in the first portion of the plurality of support patterns 152 that remain unremoved in the plurality of support patterns 152. The remaining portion of the plurality of single crystal bars 110SB and the remaining portion of the plurality of isolation insulating patterns 154 may be exposed in a space from which the portion of the support patterns 152 is removed. In some embodiments, the remaining portion of the plurality of single crystal bars 110SB and the remaining portion of the plurality of isolation insulating patterns 154 may protrude in the first horizontal direction (X direction) from the first portion of the plurality of remaining support patterns 152 toward the first recess R1.

For example, in the process of removing a portion of the buried structure 140 and the plurality of support patterns 152, a portion of the first mask layer 164 may also be removed, thereby reducing the height and width.

Referring to FIG. 17, a spacer liner material layer is formed on the exposed surface of the result of FIG. 16, a spacer buried material layer covering or overlapping the spacer liner material layer is formed, and then a portion of the spacer liner material layer and a portion of the spacer buried material layer are removed to form a spacer liner 172 covering or overlapping an inner surface of a portion of each of the spaces between the plurality of single crystal bars 110SB and the plurality of separation insulating patterns, also referred to as the plurality isolation insulating patterns 154, adjacent to each other in the vertical direction (Z direction) and a buried spacer 174 filling a portion of each of the spaces.

In some embodiments, the spacer liners 172 may be made of silicon nitride, and the buried spacers 174 may include any one of a silicon oxide, silicon oxynitride, carbon-containing silicon oxide, carbon-containing silicon nitride, and/or carbon-containing silicon oxynitride.

Thereafter, the gate dielectric layer 182 covering or overlapping the exposed surface and a word line WL covering or overlapping the gate dielectric layer 182 and filling a portion of the inside of the remaining space of the spaces between the plurality of single crystal bars 110SB and the plurality of isolation insulating patterns 154 are formed. The word line WL may be formed by forming a gate electrode material layer covering or overlapping the gate dielectric layer 182 and filling the third recess R3, and then removing a portion of the gate electrode material layer so that the rest of the gate electrode material layer remains only in a portion of the inner side of the remaining space of the spaces between the plurality of single crystal bars 110SB and the plurality of isolation insulating patterns 154.

In some embodiments, the word line WL may include a conductive barrier layer covering or overlapping the gate dielectric layer 182 and a conductive filling layer covering or overlapping the conductive barrier layer. The conductive barrier layer may include, for example, metal, conductive metal nitride, conductive metal silicide, or a combination thereof. For example, the conductive barrier layer may be made of TiN. The conductive filling layer may be formed of doped silicon, Ru, RuO, Pt, PtO, Ir, IrO, SRO(SrRuO), BSRO((Ba, Sr)RuO), CRO(CaRuO), BaRuO, La(Sr, Co)O, Ti, TiN, W, WN, Ta, TaN, TiAlN, TiSiN, TaAlN, TaSiN, or a combination thereof. In some embodiments, the conductive filling layer may include W.

Then, a plurality of capping spacers 192 at least partially filling spaces between the plurality of single crystal bars 110SB and the plurality of isolation insulating patterns 154 may be formed in the vertical direction (Z direction). One end of each of the plurality of single crystal bars 110SB facing the first recess R1 may be exposed. In some embodiments, each of the plurality of capping spacers 192 may be made of silicon nitride.

Thereafter, a plurality of first source/drain regions 222 may be formed by injecting impurities into one end of each of the plurality of single crystal bars 110SB exposed through the first recess R1.

Thereafter, a conductive material layer that conformally covers or overlaps the first recess R1 is formed, and then an etch-back process is performed to expose the substrate 101, thereby forming a conductive line that extends along the second horizontal direction (Y direction) within the first recess R1. Thereafter, a portion of the conductive line may be removed to form a plurality of bit lines BL spaced apart from each other in the second horizontal direction (Y direction). According to some embodiments, the plurality of bit lines BL may extend in the vertical direction (Z direction) and may be in contact with first source/drain regions 222 aligned in the vertical direction (D3 direction).

For example, each of the plurality of bit lines 194 may be made of any one of doped semiconductor materials, such as impurity-doped silicon and/or impurity-doped germanium, conductive metal nitrides, such as titanium nitride and/or tantalum nitride, metals, such as tungsten, titanium, and/or tantalum, and/or metal-semiconductor compounds such as tungsten silicide, cobalt silicide, and/or titanium silicide.

Then, a second buried insulating layer 196 at least partially filling the first recess R1 may be formed. In some embodiments, the second buried insulating layer 196 may be formed of silicon oxide.

Referring to FIG. 18, a portion of the first mask layer 164 and the second buried insulating layer 196 may be removed from the result of FIG. 17, and the buried structure 140 filling a second recess R2 may be removed. In some embodiments, the plurality of support patterns 152 exposed through the second recess R2 may be removed to form a fourth recess R4 communicating with the second recess R2.

In the process of forming the fourth recess R4, the plurality of single crystal bars 110SB and the plurality of isolation insulating patterns 154 may not be removed, and a portion of the plurality of single crystal bars 110SB and a portion of the plurality of isolation insulating patterns 154 may be exposed through the fourth recess R4.

For example, a portion of the plurality of single crystal bars 110SB and a portion of the plurality of isolation insulating patterns 154 may be surrounded by the spacer liner 172 and the buried spacer 174. The remaining portions of the plurality of single crystal bars 110SB and the remaining portions of the plurality of isolation insulating patterns 154 may protrude in the first horizontal direction (X direction) from the spacer liner 172 and the buried spacer 174 toward the second recess R2.

Referring to FIG. 19, in the result of FIG. 18, a portion of the plurality of single crystal bars 110SB protruding from the spacer liner 172 and the buried spacer 174 in the first horizontal direction (X direction) toward the second recess R2 may be removed. In some embodiments, a plurality of second source/drain regions 226 may be formed by injecting impurities into the other ends of the plurality of single crystal bars 110SB exposed through the second recess R2. The remaining portions among the plurality of single crystal bars 120SR after the plurality of second source/drain regions 226 are formed, may be referred to as a plurality of single crystal channel layers 224. The first source/drain region 222, the single crystal channel layer 224, and the second source/drain region 226 together may be referred to as a transistor body 220. All of the transistor bodies 220 may be made of a single crystal semiconductor material. For example, each of the first source/drain region 222, the single crystal channel layer 224, and the second source/drain region 226 may be formed of a single crystal semiconductor material. The transistor body 220, the gate dielectric layer 182, and the word line WL may include a cell transistor CTR.

Thereafter, a lower electrode material layer conformally covering or overlapping a surface exposed in the second recess R2 may be formed. The lower electrode material layer may conformally cover or overlap surfaces of the second source/drain region 226, the spacer liner 172, the buried spacer 174, and the isolation insulating pattern 154. Thereafter, a portion of the lower electrode material layer covering or overlapping the other ends of the plurality of isolation insulating patterns 154 facing the second recess R2 may be removed to form a plurality of hollow cylinder-shaped first electrodes EL1, in which a portion facing the second recess R2 in the first horizontal direction (X direction) is opened, and a portion facing the second source/drain region 226 is closed.

In some embodiments, after exposing the surfaces of the other ends of the plurality of isolation insulating patterns 154, a portion of the plurality of separation insulating patterns or plurality of isolation insulating patterns 154 may be removed from the other ends. In some embodiments, a portion of the first buried insulating layer 162 defining a partial region of the second recess R2 may be removed. In some embodiments, portions of the plurality of isolation insulating patterns 154 and the first buried insulating layer 162 may be removed by an isotropic etching process.

Referring to FIGS. 19 and 2A to 2D together, a capacitor dielectric layer DL that conformally covers or overlaps the plurality of first electrodes EL1 and a second electrode EL2 that covers or overlaps the capacitor dielectric layer DL and fills the second recess R2 may be formed to form a cell capacitor CAP including the first electrode EL1, the capacitor dielectric layer DL, and the second electrode EL2.

The capacitor dielectric layer DL may cover or overlap at least a portion of an inner surface and an outer surface of each of the plurality of first electrodes EL1 each having a cylindrical shape. In some embodiments, the capacitor dielectric layer DL may cover or overlap the whole inner surface of each of the plurality of first electrodes EL1 having a cylindrical shape and may cover or overlap a portion of an outer surface. In some other embodiments, the capacitor dielectric layer DL may cover or overlap the whole inner surface of each of the plurality of first electrodes EL1 having a cylindrical shape, and may cover or overlap the whole outer surface. The second electrode EL2 may at least partially fill the inside of each of the plurality of first electrodes EL1 having a cylindrical shape. That is, each of the plurality of first electrodes EL1 may have a U-shaped vertical cross-section rotating by 90 degrees in which the open portion faces a direction opposite to the second source/drain region 226, that is, the open portion faces the second electrode EL2.

The first electrode EL1 may include a metal, a conductive metal nitride, a conductive metal silicide, or a combination thereof. For example, the first electrode EL1 may include a high melting point metal layer, such as cobalt, titanium, nickel, tungsten, and/or molybdenum. For example, the first electrode EL1 may include a metal nitride layer, such as a titanium nitride layer, a titanium silicon nitride layer, a titanium aluminum nitride layer, a tantalum nitride layer, a tantalum silicon nitride layer, a tantalum aluminum nitride layer, and/or a tungsten nitride layer.

The capacitor dielectric layer DL may be formed of at least one selected from a high-k dielectric material having a dielectric constant higher than that of a silicon oxide and a ferroelectric material. For example, the capacitor dielectric layer may include at least one of a metal oxide or a dielectric material having a perovskite structure. For example, the capacitor dielectric layer DL includes at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), tantalum strontium bismuth (STB), bismuth iron oxide (BFO), strontium titanium oxide (SrTiO), yttrium oxide (YO), aluminum oxide (AlO), or lead scandium tantalum oxide (PbScTaO).

The second electrode EL2 may be formed of doped silicon, Ru, RuO, Pt, PtO, Ir, IrO, SRO(SrRuO), BSRO(((Ba, Sr)RuO), CRO(CaRuO), BaRuO, La(Sr, Co)O, Ti, TiN, W, WN, Ta, TaN, TiAlN, TiSiN, TiAlN, TaSiN, or a combination thereof. In some embodiments, the conductive filling layer 720 may include W.

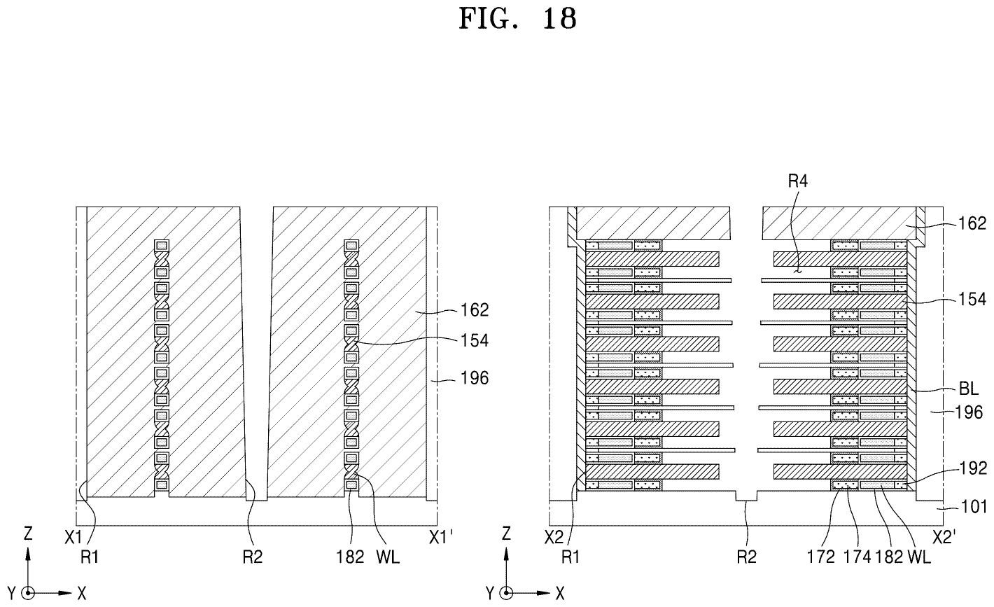

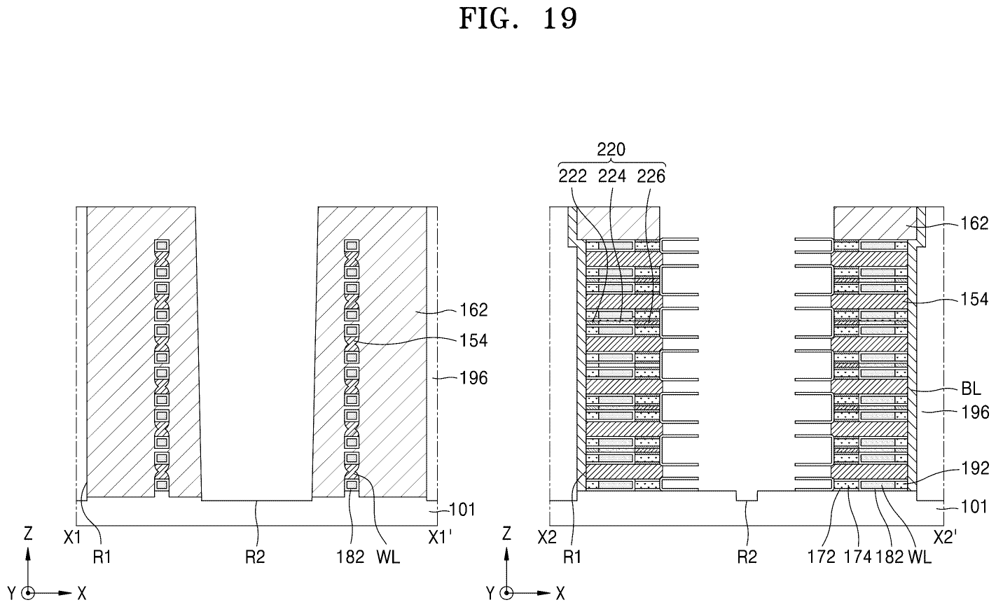

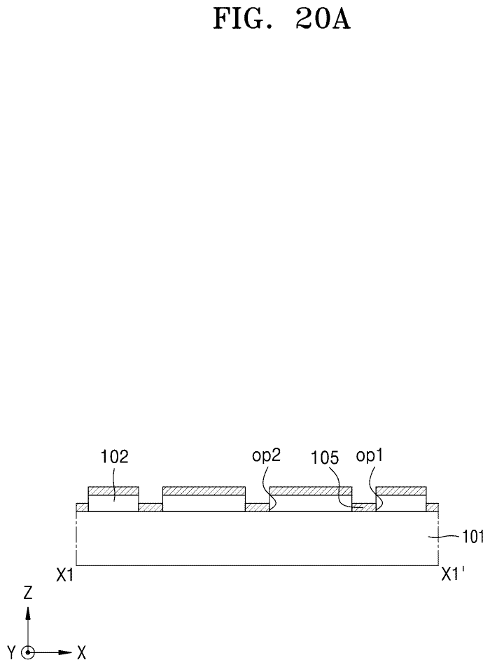

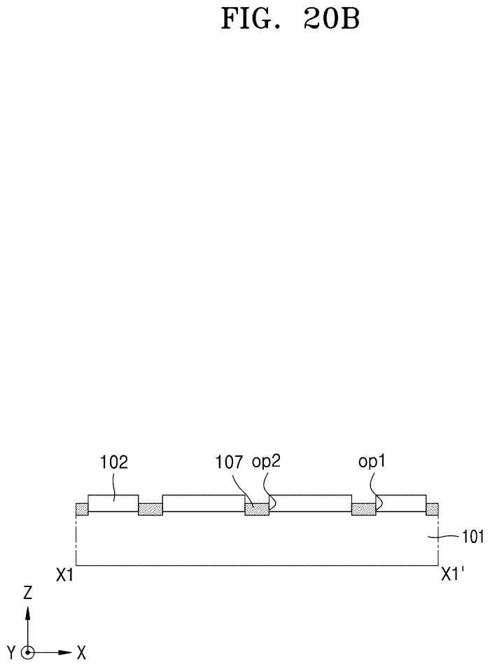

FIGS. 20A and 20B are cross-sectional views for explaining a method of manufacturing a semiconductor memory device according to some other embodiments, and illustrate portions corresponding to a cross-sectional view taken along line X1-X1′ of FIG. 4A.

Referring to FIG. 20A, a mask pattern 102 may be formed on the substrate 101, and then a metal material may be deposited on the mask pattern 102 and the substrate 101 to form a metal seed layer or metal seed pattern 105.

In some embodiments, the mask pattern 102 may include a silicon oxide layer formed through a photo process. In some embodiments, the mask pattern 102 may have a pattern shape corresponding to a set of a plurality of first openings op1 and a plurality of second openings op2.

In some embodiments, the metal seed layer or metal seed pattern 105 may be formed by a physical vapor deposition (PVD) or atomic layer deposition (ALD) process, but is not limited to the above examples. In some embodiments, the metal seed layer 105a may include a portion in contact with the substrate 101 and a portion in contact with the mask pattern 102.

Referring to FIG. 20B, a metal seed pattern (not illustrated) may be formed by removing a portion of the metal seed layer 105a arranged on the mask pattern 102 from the result of FIG. 20A. For example, the metal seed pattern may have a shape corresponding to the metal seed pattern 105 of FIG. 4B.

In some embodiments, a portion of the metal seed layer 105a may be removed through a strip process, and the remaining portion of the metal seed pattern (not shown) may be arranged in a space defined by the mask pattern 102 and the top surface of the substrate 101.

Then, a metal silicide pattern 107 may be formed from the metal seed layer 105a through a heating process. In some embodiments, a portion of the sidewall of the metal silicide pattern 107 may be in contact with the mask pattern 102.

Then, as described with reference to FIGS. 6 to 8, the patterned mold stack PMS may be formed by alternately growing the plurality of single crystal semiconductor patterns 110 and the plurality of sacrificial semiconductor patterns 120 one by one from the metal silicide pattern 107. Thereafter, the semiconductor memory device 10 may be manufactured through the manufacturing method described with reference to FIGS. 9A to 19.

In some embodiments, the mask pattern 102 may be removed together in the operation of removing the sacrificial insulating layer 134 described with reference to FIGS. 10A and 10B. In some other embodiments, the mask pattern 102 may be removed together in a strip process for removing a portion of the metal seed layer 105a described with reference to FIG. 20B. In this case, the metal seed pattern 105 described with reference to FIG. 4B may be formed.

While the inventive concept has been particularly shown and described with reference to some embodiments thereof, it will be understood that various changes in form and details may be made therein without departing from the spirit and scope of the following claims.

What is claimed is:

1. A method of manufacturing a semiconductor memory device, the method comprising:
forming a metal seed pattern having a plurality of openings on a substrate;
forming a metal silicide pattern from the substrate and the metal seed pattern;
growing a single crystal semiconductor pattern in a vertical direction at an interface between the substrate and the metal silicide pattern, wherein the vertical direction is perpendicular to the substrate; and
growing a sacrificial semiconductor pattern in the vertical direction at an interface between the metal silicide pattern and the single crystal semiconductor pattern.

2. The method of claim 1,
wherein the single crystal semiconductor pattern includes silicon (Si), and
wherein the growing of the single crystal semiconductor pattern comprises heating the metal silicide pattern under a first reaction gas including a silicon (Si) source.

3. The method of claim 2, wherein the metal silicide pattern includes gold (Au), and
wherein, in the growing of the single crystal semiconductor pattern, the metal silicide pattern forms a first eutectic layer of gold (Au)-silicon (Si).

4. The method of claim 2, wherein the first reaction gas further includes a first etching composition that is configured to remove impurities deposited on the substrate.

5. The method of claim 1,
wherein the sacrificial semiconductor pattern includes silicon (Si) and germanium (Ge), and
wherein the growing of the sacrificial semiconductor pattern comprises heating the metal silicide pattern under a second reaction gas including a silicon (Si) source and a germanium (Ge) source.

6. The method of claim 5, wherein the metal silicide pattern includes gold (Au), and
wherein, in the growing of the sacrificial semiconductor pattern, the metal silicide pattern forms a second eutectic layer of gold (Au)-silicon (Si)-germanium (Ge).

7. The method of claim 1, wherein a sidewall of the single crystal semiconductor pattern and a sidewall of the sacrificial semiconductor pattern are perpendicular to a top surface of the substrate.

8. The method of claim 1, further comprising:
forming a patterned mold stack having a plurality of vertical holes by alternately growing respective ones of a plurality of single crystal semiconductor patterns and respective ones of a plurality of sacrificial semiconductor patterns from a bottom surface of the metal silicide pattern.

9. The method of claim 8, wherein a horizontal width of each of the plurality of vertical holes is constant regardless of a distance to the substrate in the vertical direction.

10. The method of claim 8, further comprising:
at least partially filling the plurality of vertical holes with a sacrificial insulating layer; and
forming a plurality of recesses that extend into the patterned mold stack and the sacrificial insulating layer in the vertical direction by anisotropically etching the patterned mold stack and the sacrificial insulating layer,
wherein the plurality of recesses have a tapered shape in which a horizontal width becomes narrower towards the substrate in the vertical direction.

11. A method of manufacturing a semiconductor memory device, the method comprising:
forming a metal seed pattern on a substrate;
forming a metal silicide pattern from the substrate and the metal seed pattern;
forming a eutectic layer of a metal-semiconductor material by heating the metal silicide pattern; and
forming a patterned mold stack having a plurality of vertical holes exposing the substrate by alternately growing respective ones of a plurality of single crystal semiconductor patterns and respective ones of a plurality of sacrificial semiconductor patterns from a bottom surface of the eutectic layer.

12. The method of claim 11, wherein an inner sidewall of the patterned mold stack defining the plurality of vertical holes is perpendicular to a top surface of the substrate.

13. The method of claim 11, wherein the plurality of single crystal semiconductor patterns and the plurality of sacrificial semiconductor patterns are epitaxially grown in a direction away from a top surface of the substrate.

14. The method of claim 11, wherein the forming of the eutectic layer is performed in a temperature range of about 250° C. to about 1,500° C.

15. The method of claim 11, wherein a ratio of a number of atoms of a metal to a total number of atoms in the eutectic layer is about 0.1 to about 0.3.

16. The method of claim 11,
wherein the plurality of single crystal semiconductor patterns includes silicon (Si), and
wherein the plurality of sacrificial semiconductor patterns includes silicon (Si) and germanium (Ge).

17. A method of manufacturing a semiconductor memory device, the method comprising:
forming a metal seed pattern having a plurality of openings on a substrate;
forming a metal silicide pattern from the substrate and the metal seed pattern;
forming a eutectic layer of a metal-semiconductor material by heating the metal silicide pattern;
forming a patterned mold stack having a plurality of vertical holes by alternately growing respective ones of a plurality of single crystal semiconductor patterns and respective ones of a plurality of sacrificial semiconductor patterns from a bottom surface of the eutectic layer;
at least partially filling the plurality of vertical holes with a sacrificial insulating layer;
forming a plurality of recesses that extend into the patterned mold stack and the sacrificial insulating layer in a vertical direction by anisotropically etching the patterned mold stack and the sacrificial insulating layer; and
forming a buried insulating structure in the plurality of recesses,
wherein the plurality of vertical holes have a constant horizontal width regardless of distance from the substrate, and the plurality of recesses have a tapered shape in which a width becomes narrower towards a top surface of the substrate.

18. The method of claim 17,
wherein the plurality of single crystal semiconductor patterns includes silicon (Si),
wherein the plurality of sacrificial semiconductor patterns includes silicon (Si) and germanium (Ge), and
wherein the forming of the patterned mold stack comprises alternately contacting the metal silicide pattern with a first reaction gas including a first silicon (Si) source, and a second reaction gas including a second silicon (Si) source and a germanium (Ge) source, after heating the metal silicide pattern.

19. The method of claim 17, wherein the plurality of single crystal semiconductor patterns and the plurality of sacrificial semiconductor patterns are epitaxially grown in a direction away from the top surface of the substrate.

20. The method of claim 17, wherein a ratio of a number of atoms of a metal to a total number of atoms in the eutectic layer is about 0.1 to about 0.3.
